(19) United States
(12) Patent Application Publication
(10) Pub. No.: US 2026/0231790 A1
(43) Pub. Date: Aug. 6, 2026

(54) DIELECTRIC INTERPOSER FOR PACKAGING STRUCTURES AND METHODS OF FORMING THE SAME

(71) Applicant: Taiwan Semiconductor Manufacturing Company Limited, Hsinchu (TW)

(72) Inventors: Tzu Jung Tien, Hsinchu (TW); Jen-Yuan Chang, Hsinchu (TW)

(21) Appl. No.: 19/045,593

(22) Filed: Feb. 5, 2025

(51) Int. Cl. H01L 23/538; H01L 21/48; H01L 23/00; H01L 23/367; H01L 25/07

(52) U.S. Cl. CPC H10W 70/611; H10W 40/22; H10W 70/095; H10W 70/65; H10W 90/401; H10W 80/312; H10W 80/327; H10W 90/00; H10W 90/794

(57) ABSTRACT

A device structure may be provided by: forming an array of through-dielectric via structures in a dielectric substrate; forming dielectric material layers and metal interconnect structures over the dielectric substrate; forming on-interposer bonding pads at a topmost level of the dielectric material layers; attaching at least one semiconductor die to the on-interposer bonding pads; and thinning a backside portion of the dielectric substrate such that bottom end surfaces of the through-dielectric via structures are exposed upon thinning of the backside portion of the dielectric substrate.

### BACKGROUND

Manufacturing efficiency in traditional silicon-based interposer substrates used in system-on-integrated-chip (SoIC) devices is constrained by use of a circular semiconductor wafer as an initial substrate material, and by inherent limitations in the mechanical properties of silicon, resulting in inefficient use of substrate area and reduced yield for large interposers. Additionally, challenges such as crack propagation during processing, warpage in larger interposer designs, and defects associated with dielectric-to-dielectric and metal-to-metal bonding interfaces contribute to increased manufacturing complexity and costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top-down view of a dielectric substrate according to an embodiment of the present disclosure.

FIG. 1B is a vertical cross-sectional view of a region of the dielectric substrate according to the vertical cross-sectional plane B-B′ in FIG. 1A.

FIG. 2A is a vertical cross-sectional view of a region of the dielectric substrate after formation of an array of via cavities and moat trenches according to an embodiment of the present disclosure.

FIG. 2B is a top-down view of the region of the dielectric substrate of FIG. 2A. The vertical plane A-A′ is the cut plane of the vertical cross-sectional view of FIG. 2A.

FIG. 2C is a top-down view of a first alternative configuration of the dielectric substrate of FIGS. 2A and 2B.

FIG. 2D is a top-down view of a second alternative configuration of the dielectric substrate of FIGS. 2A and 2B.

FIG. 2E is a top-down view of a third alternative configuration of the dielectric substrate of FIGS. 2A and 2B.

FIG. 3A is a vertical cross-sectional view of a region of the dielectric substrate after formation of an array through-dielectric via structures and substrate metallic edge seal structures according to an embodiment of the present disclosure.

FIG. 3B is a top-down view of the region of the dielectric substrate of FIG. 3A. The vertical plane A-A′ is the cut plane of the vertical cross-sectional view of FIG. 3A.

FIG. 3C is a top-down view of a first alternative configuration of the dielectric substrate of FIGS. 3A and 3B.

FIG. 3D is a top-down view of a second alternative configuration of the dielectric substrate of FIGS. 3A and 3B.

FIG. 3E is a top-down view of a third alternative configuration of the dielectric substrate of FIGS. 3A and 3B.

FIG. 4A is a vertical cross-sectional view of a region of an interposer wafer after formation of a dielectric stress relief layer, dielectric material layers, metal interconnect structures, on-interposer bonding pads, and interconnect-level metallic edge seal structures according to an embodiment of the present disclosure.

FIG. 4B is a top-down view of the region of the interposer wafer of FIG. 4A. The vertical plane A-A′ is the cut plane of the vertical cross-sectional view of FIG. 4A.

FIG. 4C is a top-down view of a first alternative configuration of the interposer wafer of FIGS. 4A and 4B.

FIG. 4D is a top-down view of a second alternative configuration of the interposer wafer of FIGS. 4A and 4B.

FIG. 4E is a top-down view of a third alternative configuration of the interposer wafer of FIGS. 4A and 4B.

FIG. 5A is a vertical cross-sectional view of a region of a bonded assembly of the interposer wafer and semiconductor dies according to an embodiment of the present disclosure.

FIG. 5B is a top-down view of the region of the bonded assembly of FIG. 5A. The vertical plane A-A′ is the cut plane of the vertical cross-sectional view of FIG. 5A.

FIG. 5C is a top-down view of a first alternative configuration of the bonded assembly of FIGS. 5A and 5B.

FIG. 5D is a top-down view of a second alternative configuration of the bonded assembly of FIGS. 5A and 5B.

FIG. 5E is a top-down view of a third alternative configuration of the bonded assembly of FIGS. 5A and 5B.

FIG. 6 is a vertical cross-sectional view of a region of a reconstituted after comprising a die frame matrix according to an embodiment of the present disclosure.

FIG. 7A is a vertical cross-sectional view of a region of the reconstituted wafer after planarizing the die frame matrix according to an embodiment of the present disclosure.

FIG. 7B is a top-down view the region of the reconstituted wafer of FIG. 7A. The vertical plane A-A′ is the cut plane of the vertical cross-sectional view of FIG. 7A.

FIG. 8 is a vertical cross-sectional view of a structure formed by attaching a carrier wafer to the reconstituted wafer according to an embodiment of the present disclosure.

FIG. 9 is a vertical cross-sectional view of the structure including the reconstituted wafer and the carrier wafer after removing a backside portion of the dielectric substrate according to an embodiment of the present disclosure.

FIG. 10 is a vertical cross-sectional view of the structure including the reconstituted wafer and the carrier wafer after formation of backside bonding pads and solder material portions according to an embodiment of the present disclosure.

FIG. 11 is a vertical cross-sectional view of the reconstituted wafer after detaching the carrier wafer according to an embodiment of the present disclosure.

FIG. 12A is a vertical cross-sectional view of a composite die after dicing the structure of FIG. 10.

FIG. 12B is a top-down view of the composite die of FIG. 12A. The vertical plane A-A′ is the cut plane of the vertical cross-sectional view of FIG. 12A.

FIG. 13 is a vertical cross-sectional view of an assembly including an assembly of the composite die and a packaging substrate according to an embodiment of the present disclosure.

FIG. 14 is a vertical cross-sectional view of an assembly of the composite die, the packaging substrate, and a lid structure according to an embodiment of the present disclosure.

FIG. 15 is a vertical cross-sectional view of an assembly of the composite die, the packaging substrate, the lid structure, and a printed circuit board according to an embodiment of the present disclosure.

FIG. 16 is a vertical cross-sectional view of a first alternative configuration of the assembly of the composite die, the packaging substrate, the lid structure, and the printed circuit board according to an embodiment of the present disclosure.

FIG. 17 is a vertical cross-sectional view of a second alternative configuration of the assembly of the composite die, the packaging substrate, the lid structure, and the printed circuit board according to an embodiment of the present disclosure.

FIG. 18 is a first flowchart illustrating steps for forming a device structure according to an embodiment of the present disclosure.

FIG. 19 is a second flowchart illustrating steps for forming a device structure according to an embodiment of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. A first physical element is “embedded” with a second physical element if the entire volume of the first element is located within a hypothetical volume defined by a set of hypothetical surfaces having the least total surface area selected from all sets of hypothetical surfaces containing the entirety of the outer surfaces of the second element and topologically homeomorphic to a spherical surface. Such a set of hypothetical surfaces covers each opening, if present, in the outer surfaces with a minimum-area surface segment selected from all possible opening-free surface segments. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Generally, an interposer that may be bonded (i.e., dielectric-to-dielectric bonding and/or metal-metal bonding) with semiconductor dies uses a silicon-based interposer containing a patterned portion of a silicon wafer having a circular area. The number of silicon-based interposers that may be obtained from a silicon wafer is limited by the edge loss due to the peripheral regions of the circular silicon wafer that are not incorporated into the silicon-based interposers. Thus, use of circular silicon wafers results in waste of a relative large wafer area for the purpose of production of silicon-based interposers.

Embodiments of the present disclosure are directed to manufacture of a composite die containing a dielectric interposer. A dielectric interposer including a diced portion of a dielectric substrate may replace a silicon-based interposer. The dielectric substrate may have a rectangular area so that the utilized fraction of the area of the dielectric substrate for the purpose of manufacture of the dielectric interposers is 100% or close to 100%. The rectangular dielectric substrate may be composed of a dielectric material such as silicon oxide, aluminum oxide, a transition metal oxide, or a combination thereof. The rectangular dielectric substrate includes a two-dimensional array of unit areas. Through-dielectric via structures may be formed within each unit area of the dielectric substrate. Dielectric material layers, interconnect-level metal structures, and on-interposer bonding pads may be formed over the front horizontal surface of the dielectric substrate. Semiconductor dies may be bonded to the on-interposer bonding pads and the topmost layer selected from the dielectric material layers using dielectric-to-dielectric and/or metal-to-metal bonding.

According to an aspect of the present disclosure, the gaps between the semiconductor dies may be filled with a gap fill material, which may comprise a molding compound material or a planarizable dielectric material such as silicon oxide. Substrate metallic edge seal structures may be formed through the dielectric substrate to prevent crack propagation during a dicing process. The substrate metallic edge seal structures may be interconnected with one another within a unit area or across neighboring unit areas to reduce crack propagation, mechanical stress accumulation, and/or electrical charge accumulation within the dielectric substrate.

Further, interconnect-level metallic edge seal structures may be formed through the dielectric material layers to reduce crack propagation, mechanical stress accumulation, and/or electrical charge accumulation within the dielectric material layers. Warpage of a reconstituted wafer including a two-dimensional array of dielectric interposers and semiconductor die sets may be reduced by controlling die-to-die distances above 10 microns, and optionally by incorporating a dielectric stress relief layer comprising a dielectric material having a lower Young's modulus than any material in the dielectric material layers.

Thus, embodiments of the present disclosure provide enhanced utilization of a substrate material for interposers, increases thermal isolation and device performance for interposers, and reduces manufacturing complexity and cost for the interposers. Various aspects of the present disclosure are now described with reference to accompanying drawings.

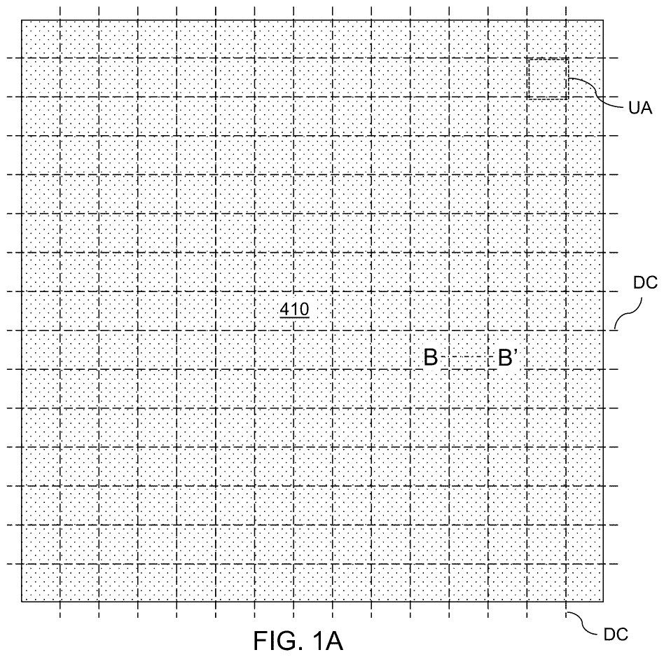

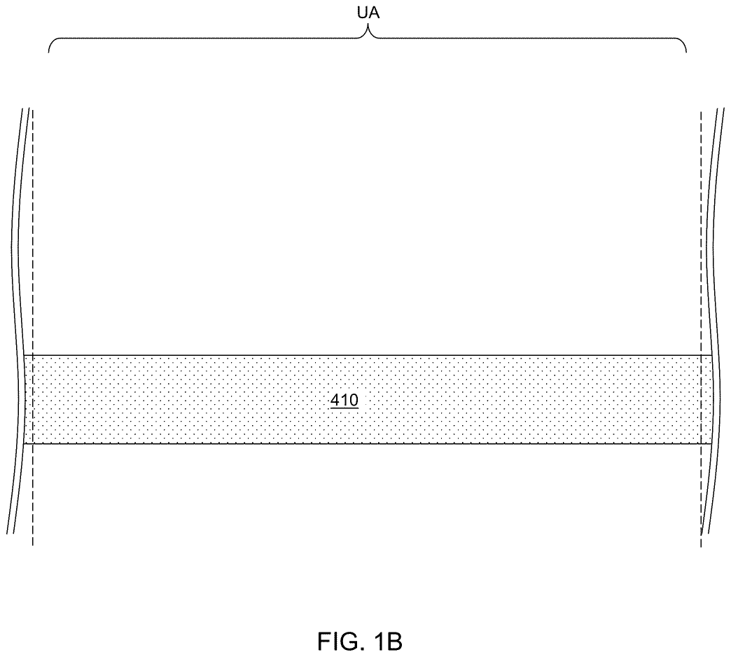

Referring to FIGS. 1A and 1B, a dielectric substrate 410 according to an embodiment of the present disclosure is illustrated. The dielectric substrate 410 comprises, and/or consists essentially of, at least one inorganic dielectric material such as silicon oxide, aluminum nitride, a transition metal oxide (such as titanium oxide or zirconium oxide), or a combination thereof. In one embodiment, the dielectric substrate 410 comprises amorphous silicon oxide, i.e., glass. According to an aspect of the present disclosure, the dielectric substrate 410 may have a rectangular shape in a plan view such as a top-down view so that the utilized fraction of the area of the dielectric substrate for the purpose of manufacture of the dielectric interposers is 100% or close to 100%. The rectangular dielectric substrate may be composed of a dielectric material such as silicon oxide, aluminum oxide, a transition metal oxide, or a combination thereof.

The lateral dimensions (such as the length and the width) of the dielectric substrate 410 may be in a range from 300 mm to 600 mm, although lesser or greater lateral dimensions may also be used. Generally, the lateral dimensions of the dielectric substrate 410 may be selected to provide a plurality of unit areas UA. The boundaries between neighboring pairs of unit areas UA constitute dicing channels DC. Each unit area UA corresponds to an area of the dielectric substrate 410 that may be diced into a respective dielectric interposer. The width of each unit area may be in a range from 8 mm to 30 mm, although lesser or greater widths may also be used. The length of each unit area may be in a range from 8 mm to 30 mm, although lesser or greater lengths may also be used. The thickness of the dielectric substrate 410 may be in a range from 20 microns to 100 microns, such as from 30 microns to 60 microns, although lesser or greater thicknesses may also be used.

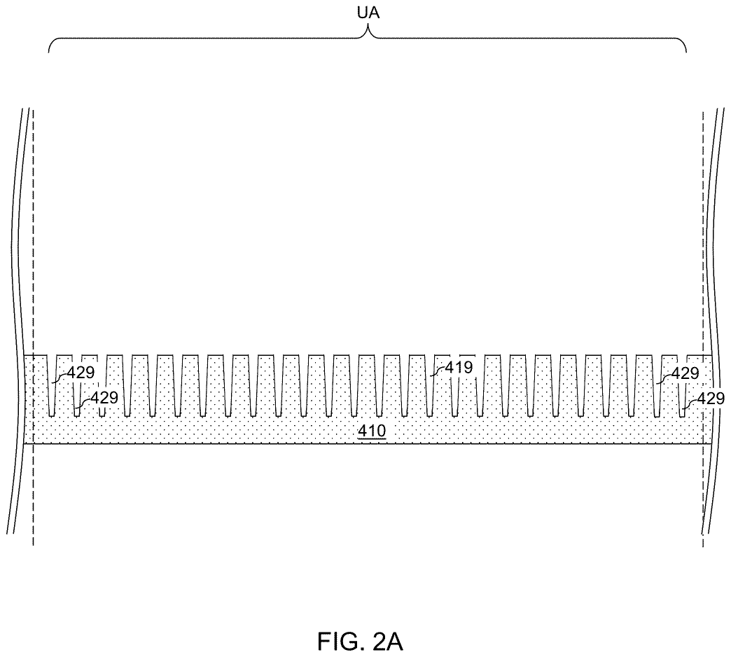

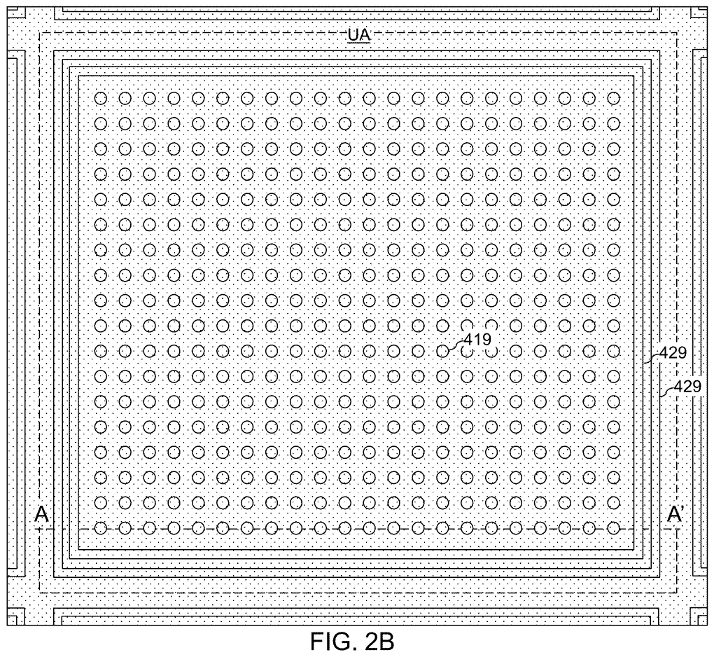

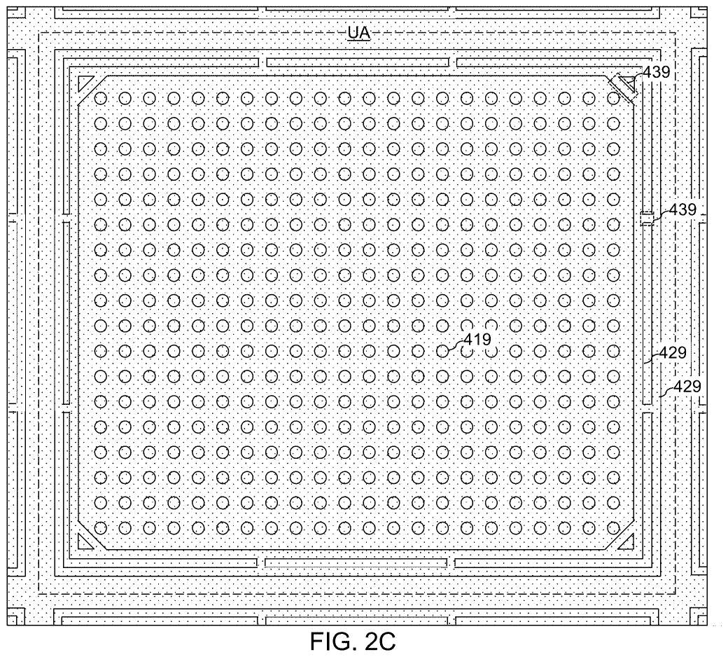

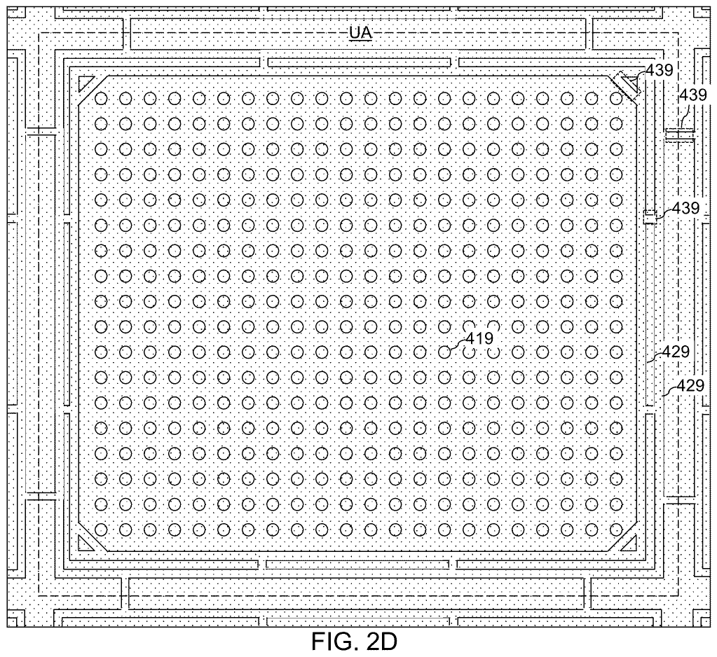

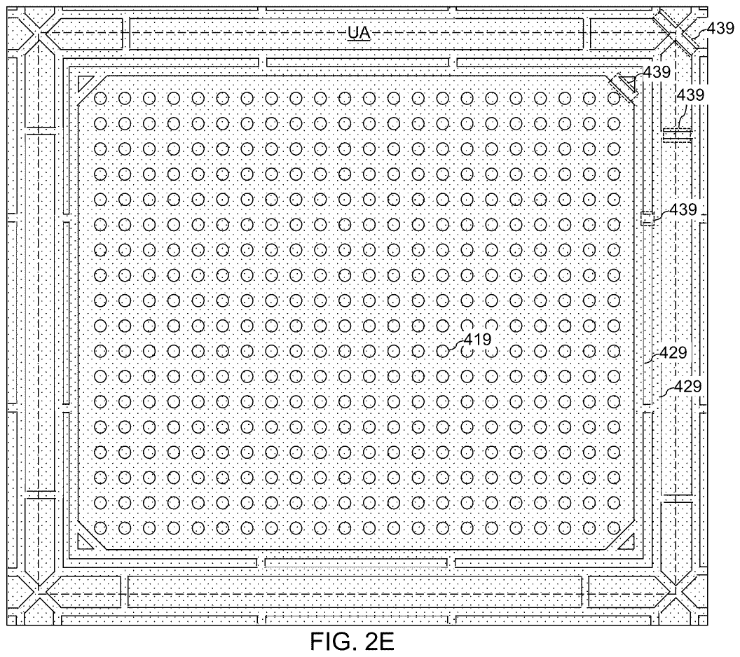

FIG. 2A is a vertical cross-sectional view of a region of the dielectric substrate 410 after formation of an array of via cavities 419 and moat trenches 429 according to an embodiment of the present disclosure. FIG. 2B is a top-down view of the region of the dielectric substrate 410 of FIG. 2A. The vertical plane A-A′ is the cut plane of the vertical cross-sectional view of FIG. 2A. FIG. 2C is a top-down view of a first alternative configuration of the dielectric substrate 410 of FIGS. 2A and 2B. FIG. 2D is a top-down view of a second alternative configuration of the dielectric substrate 410 of FIGS. 2A and 2B. FIG. 2E is a top-down view of a third alternative configuration of the dielectric substrate 410 of FIGS. 2A and 2B.

Referring to FIGS. 2A-2E, an etch mask layer (not illustrated) may be formed over the top surface of the dielectric substrate 410, and may be patterned to form various patterns of openings. In one embodiment, the etch mask layer may comprise a patterned photoresist layer. The etch mask layer may have the same pattern of openings within each unit area UA. An anisotropic etch process may be performed to transfer the pattern of the openings in the etch mask layer into an upper portion of the dielectric substrate 410. Arrays of via cavities 419 and moat trenches 429 may be formed in the upper portion of the dielectric substrate 410. The etch mask layer may be subsequently removed, for example, by ashing.

Each array of via cavities 419 may be formed within a respective unit area UA. In one embodiment, each array of via cavities 419 may be laterally surrounded by a respective set of at least one moat trench 429 that is formed within the respective unit area UA. In one embodiment, the arrays of via cavities 419 may be formed in the upper portion of the dielectric substrate 410 such that the dielectric substrate 410 comprises a two-dimensional array of unit areas UA and each array of via cavities 419 may be formed within a respective one of the unit areas UA. Each via cavity 419 may be a discrete via cavity that is not adjoined to any other via cavity 419. Each array of via cavities 419 may be formed as a two-dimensional periodic array of via cavities 419 such as a rectangular periodic array of via cavities 419 or a hexagonal periodic array of via cavities 419. Each via cavity 419 may have a horizontal cross-sectional shape of a circle, an ellipse, a polygon (such as a rectangle), or a rounded polygon (such as a rounded rectangle).

The maximum top lateral dimension of each via cavity 419, such as the diameter of the via cavity 419 in the topmost portion, may be in a range from 40 microns 300 microns, although lesser or greater maximum top lateral dimensions may also be used. The maximum bottom lateral dimension of each via cavity 419, such as the diameter of the via cavity 419 in the bottommost portion, may be in a range from 20 microns 270 microns, although lesser or greater maximum bottom lateral dimensions may also be used. The total number of the via cavities 419 may be in a range from 2⁴ to 2¹⁶, although lesser or greater total numbers may also be used. In one embodiment, all surfaces of the arrays of via cavities 419 are dielectric surfaces, which are surfaces of the dielectric substrate 410. In one embodiment, each of the via cavities 419 may comprise a respective straight sidewall that extends from the front surface of the dielectric substrate 410 toward the backside surface of the dielectric substrate 410 by a depth that is less than the thickness of the dielectric substrate 410. The depth of the via cavities 419 may be in a range from 5 microns to 40 microns, such as from 10 microns to 20 microns, although lesser or greater depths may also be used.

According to an aspect of the present disclosure, at least one moat trench 429 laterally surrounding a respective array of via cavities 419 may be formed in the upper portion of the dielectric substrate 410 within each unit area UA. As used herein, a moat trench refers to a trench that laterally surrounds an area. Each of the moat trenches 429 laterally surrounds a respective array of via cavities 419. The at least one moat trench 429 may be a single moat trench 429, or a plurality of nested moat trenches 429. The maximum top width of each moat trench 429 may be in a range from 40 microns 300 microns, although lesser or greater maximum top widths may also be used. The maximum bottom width of each moat trench 429 may be in a range from 20 microns 270 microns, although lesser or greater maximum bottom widths may also be used. Each moat trench 429 may have about the same depth as the via cavities 419.

In embodiments in which a plurality of moat trenches 429 may be formed within each unit area UA, the plurality of moat trenches 429 may be disconnected from one another as illustrated in FIG. 2B. Alternatively, the plurality of moat trenches 429 within each unit area UA may be interconnected with one another by connecting cavities 439 as illustrated in FIGS. 2C, 2D, and 2E. Further, additional connecting cavities 439 may be formed in corner regions of a moat trench 429 to provide non-orthogonal lateral connections between two adjoined orthogonal segments of the moat trench 429 as illustrated in FIGS. 2D, 2D, and 2E. In addition, parallel neighboring segments of neighboring pairs of moat trenches 429 in neighboring pairs of unit areas UA may be interconnected to each other by yet additional connecting cavities 439 as illustrated in FIGS. 2D and 2E. Further, corner segments of moat trenches 429 may be interconnected with one another at corners of the unit areas UA at which a plurality of unit areas UA are adjoined with one another by further additional connecting cavities 439 as illustrated in FIG. 2E. Each connecting cavity 439 may have approximately the same width and approximately the same depth as the moat trenches 429. The various connecting cavities 439 may be subsequently used to form connecting metallic structures therein, which provide structural support to a reconstituted wafer during dicing into dielectric interposers in a subsequent processing step.

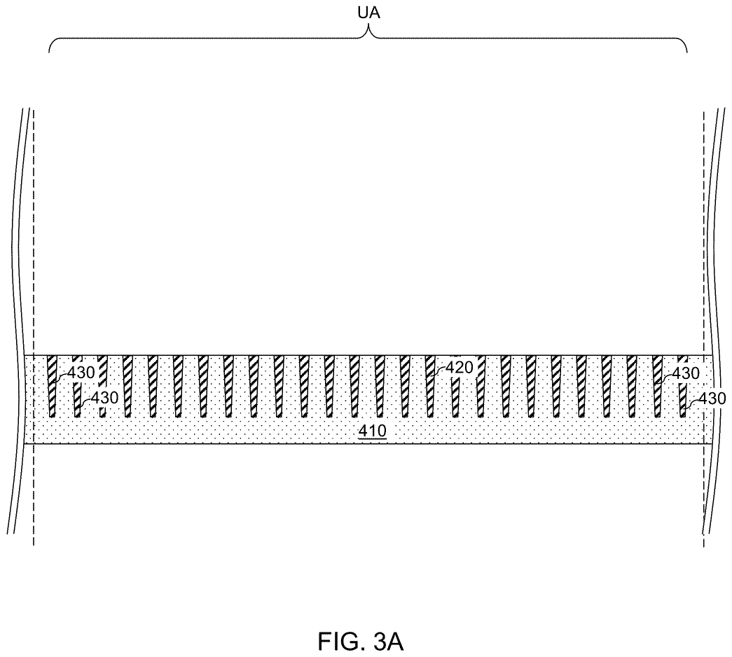

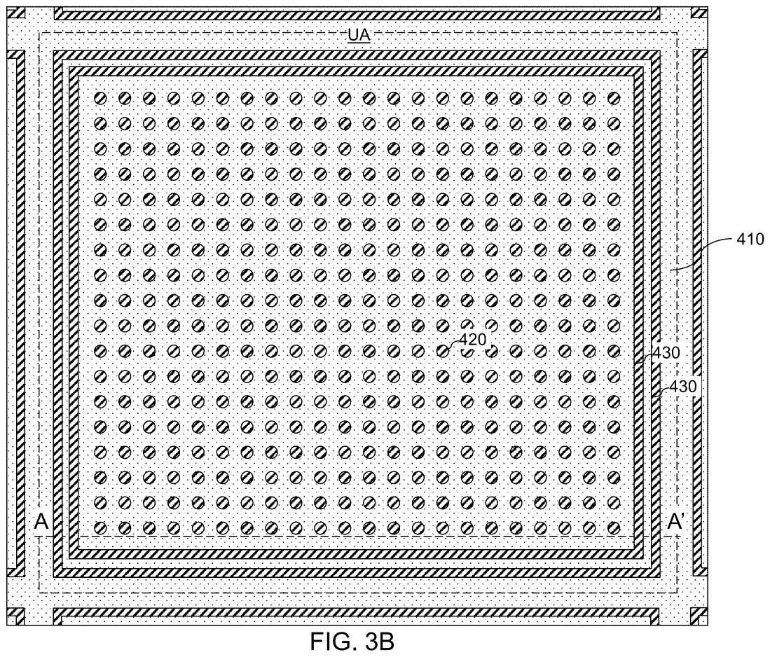

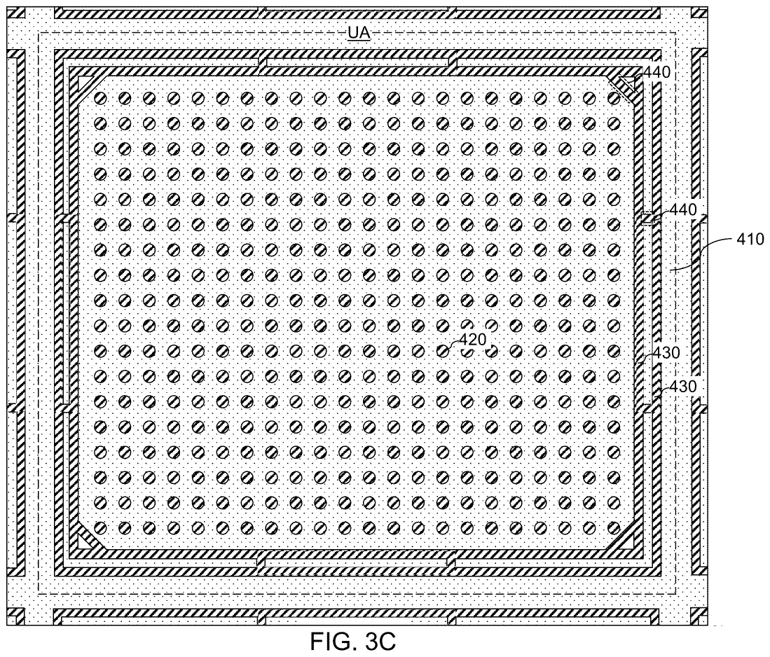

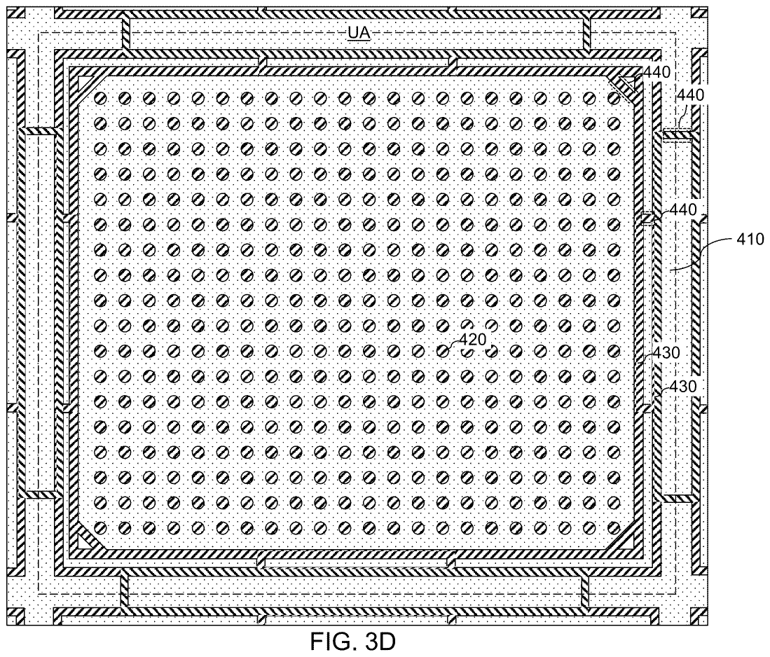

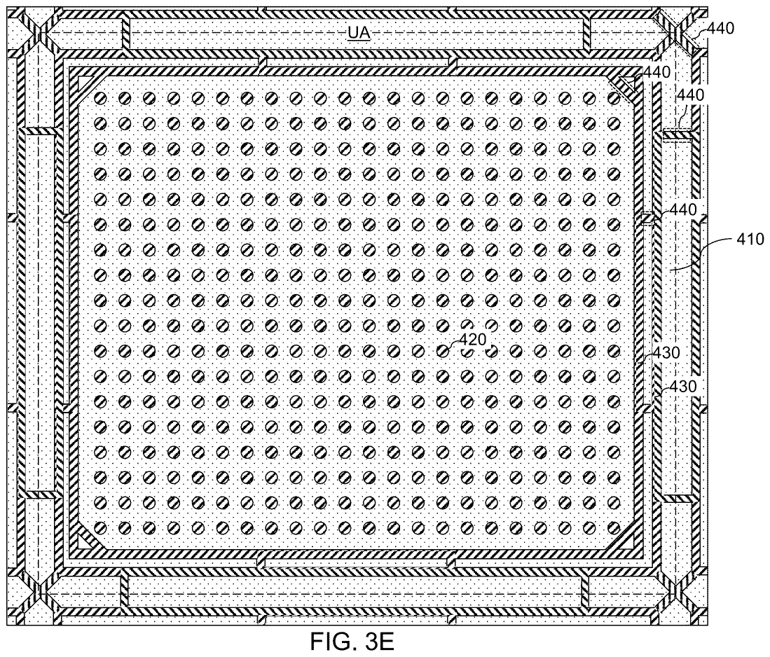

FIG. 3A is a vertical cross-sectional view of a region of the dielectric substrate 410 after formation of an array through-dielectric via structures 420 and substrate metallic edge seal structures 430 according to an embodiment of the present disclosure. FIG. 3B is a top-down view of the region of the dielectric substrate 410 of FIG. 3A. The vertical plane A-A′ is the cut plane of the vertical cross-sectional view of FIG. 3A. FIG. 3C is a top-down view of a first alternative configuration of the dielectric substrate 410 of FIGS. 3A and 3B. FIG. 3D is a top-down view of a second alternative configuration of the dielectric substrate 410 of FIGS. 3A and 3B. FIG. 3E is a top-down view of a third alternative configuration of the dielectric substrate 410 of FIGS. 3A and 3B.

Referring to FIGS. 3A-3E, at least one metallic material may be deposited in the array of via cavities 419 and the moat trenches 429 and over the front surface (i.e., the top surface) of the dielectric substrate 410. The at least one metallic material may comprise a metallic diffusion barrier material (such as TiN, TaN, WN, or MoN) and a metallic fill material (such as Cu, W, Ti, Ta, Mo, etc.). For example, the metallic diffusion barrier material may be deposited by physical vapor deposition or chemical vapor deposition. The thickness of the metallic diffusion barrier material on the sidewalls of the via cavities 419 and the moat trenches 429 may be in a range from 50 nm to 500 nm, although lesser or greater thicknesses may also be used. The metallic fill material may be deposited by electroplating, chemical vapor deposition, or physical vapor deposition, and may fill the remaining volumes of the via cavities 419 and the moat trenches 429.

Portions of the at least one metallic material that are deposited over the horizontal plane including the top surface of the dielectric substrate 410 may be removed by performing a planarization process, which may comprise a chemical mechanical polishing process and/or a recess etch process. Remaining vertically-extending portions of the at least one metallic material filling the via cavities 419 comprise through-dielectric via structures 420. Remaining portions of the at least one metallic material filling the moat trenches 429 and the optional connecting cavities 439 comprise substrate metallic edge seal structures 430 that are located entirety within the dielectric substrate 410 and function as edge seal structures upon dicing the dielectric substrate 410 along the dicing channels DC located at boundaries of the unit areas UA.

Generally, arrays of through-dielectric via structures 420 may be formed in the upper portion of the dielectric substrate 410. The arrays of through-dielectric via structures 420 comprise remaining portions of the metallic material filling the arrays of via cavities 419. In one embodiment, each of the through-dielectric via structures 420 may be formed directly on the dielectric surfaces, which are dielectric sidewalls of the dielectric substrate 410. In one embodiment, all sidewalls of the through-dielectric via structures 420 are in direct contact with the dielectric substrate 410.

The substrate metallic edge seal structures 430 may be formed in the moat trenches 429. Each substrate metallic edge seal structure 430 laterally surrounds a respective array of through-dielectric via structures 420. In one embodiment, a subset of the substrate metallic edge seal structures 430 comprises wall portions and lateral protrusion portions 440 that extend outward from the wall portions. Each of the lateral protrusion portions 440 may be formed within the volume of a respective connecting cavity 439.

In embodiments in which a plurality of substrate metallic edge seal structures 430 may be formed within each unit area UA, the plurality of substrate metallic edge seal structures 430 may be disconnected from one another as illustrated in FIG. 3B. Alternatively, the plurality of substrate metallic edge seal structures 430 within each unit area UA may be interconnected with one another by lateral protrusion portions 440 as illustrated in FIGS. 3C, 3D, and 3E. Further, additional lateral protrusion portions 440 may be formed in corner regions of a substrate metallic edge seal structure 430 to provide non-orthogonal lateral connections between two adjoined orthogonal segments of the substrate metallic edge seal structure 430 as illustrated in FIGS. 3D, 3D, and 3E. In addition, parallel neighboring segments of neighboring pairs of substrate metallic edge seal structures 430 in neighboring pairs of unit areas UA may be interconnected to each other by yet additional lateral protrusion portions 440 as illustrated in FIGS. 3D and 3E. Further, corner segments of substrate metallic edge seal structures 430 may be interconnected with one another at corners of the unit areas UA at which a plurality of unit areas UA are adjoined with one another by further additional lateral protrusion portions 440 as illustrated in FIG. 3E. Each lateral protrusion portion 440 may have approximately the same width and approximately the same depth as the substrate metallic edge seal structures 430. The various lateral protrusion portions 440 are connecting metallic structures that provide structural support to the wall portions of the substrate metallic edge seal structures 430 during dicing of a reconstituted wafer into dielectric interposers in a subsequent processing step.

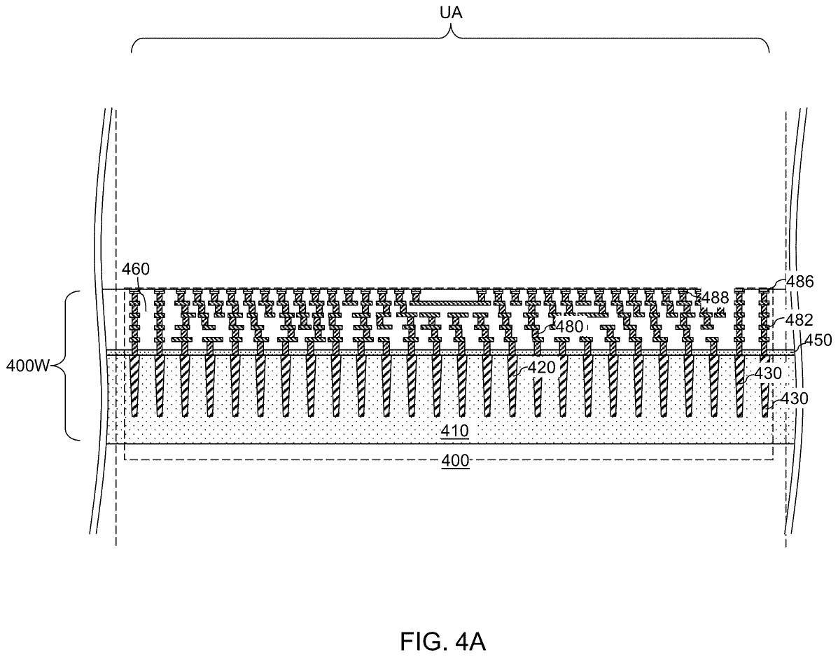

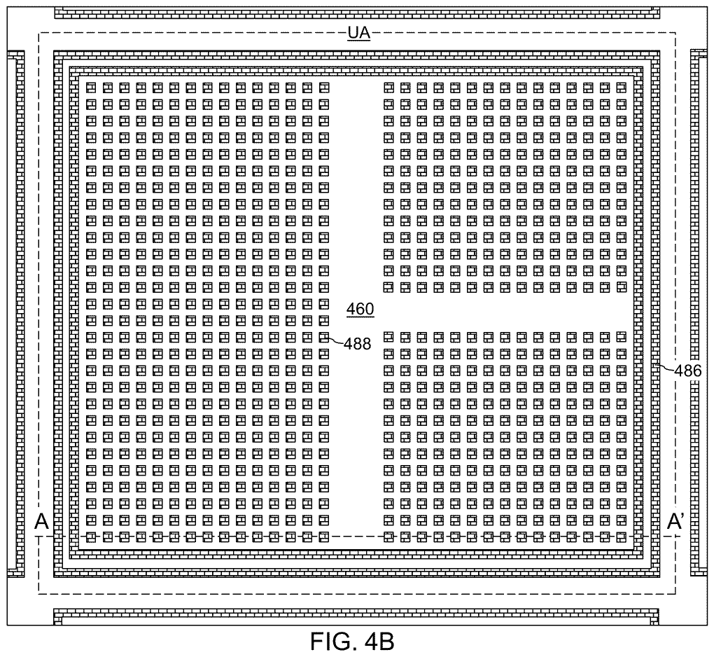

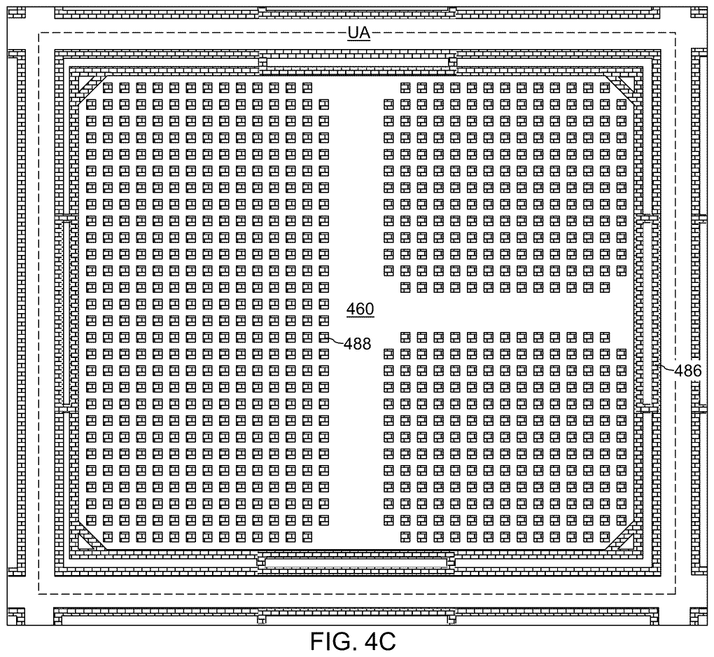

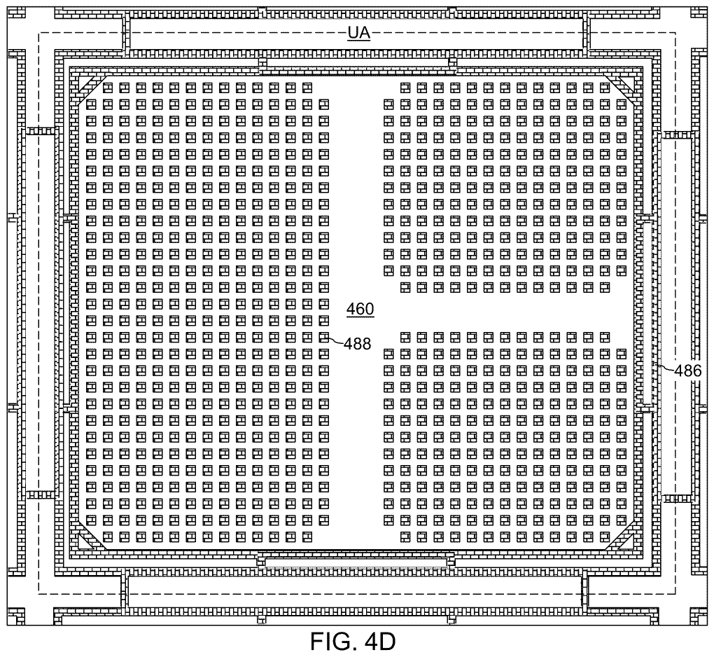

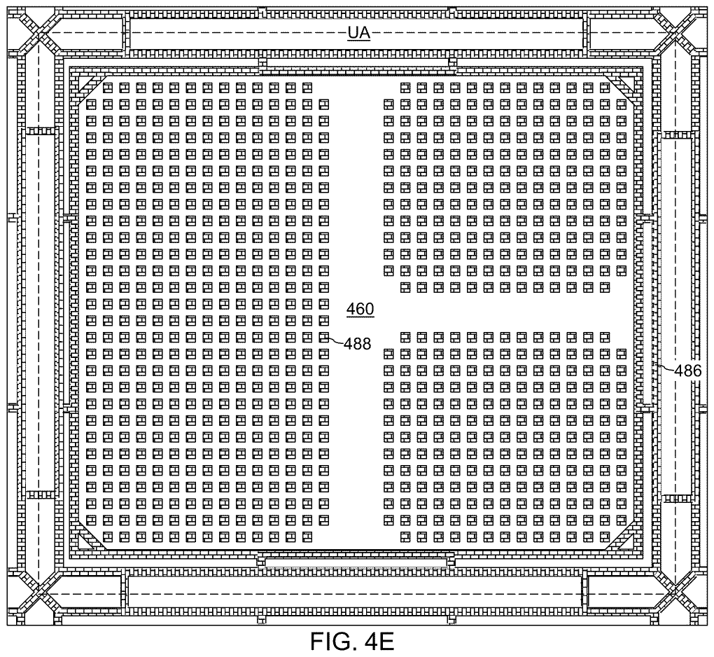

FIG. 4A is a vertical cross-sectional view of a region of an interposer wafer 400W after formation of a dielectric stress relief layer 450, dielectric material layers 460, metal interconnect structures 480, on-interposer bonding pads 488, and interconnect-level metallic edge seal structures 482 according to an embodiment of the present disclosure. FIG. 4B is a top-down view of the region of the interposer wafer 400W of FIG. 4A. The vertical plane A-A′ is the cut plane of the vertical cross-sectional view of FIG. 4A. FIG. 4C is a top-down view of a first alternative configuration of the interposer wafer 400W of FIGS. 4A and 4B. FIG. 4D is a top-down view of a second alternative configuration of the interposer wafer 400W of FIGS. 4A and 4B. FIG. 4E is a top-down view of a third alternative configuration of the interposer wafer 400W of FIGS. 4A and 4B.

Referring to FIGS. 4A-4E, an optional dielectric stress relief layer 450 and dielectric material layers 460 may be formed over the top surface of the dielectric substrate 410. Interconnect-level metal structures (480, 482) may be formed within the optional dielectric stress relief layer 450 and the dielectric material layers 460. The interconnect-level metal structures (480, 482) comprise metal interconnect structures 480 and interconnect-level metallic edge seal structures 482. Within each unit area UA, the metal interconnect structures 480 may be electrically connected to the array of through-dielectric via structures 420 to provide electrically active conductive paths for transmitting signals and power supply voltages through the dielectric stress relief layer 450 and the dielectric material layers 460. Within each unit area UA, at least one interconnect-level metallic edge seal structure 482 may extend along inside the boundary of the unit area UA to form a vertical stack of ring-shaped metallic structures without lateral openings therethrough. The interconnect-level metallic edge seal structures 482 may have an areal overlap with the substrate metallic edge seal structures 430 in a plan view, and may be electrically connected to the substrate metallic edge seal structures 430.

Generally, the dielectric material layers 460 comprise, and/or consist essentially of, at least one inorganic dielectric material. The at least one inorganic dielectric material of the dielectric material layers 460 may comprise silicon oxide, organosilicate glass, silicon nitride, silicon carbide nitride, aluminum oxide, silicon oxynitride, and/or at least one dielectric transition metal oxide. Despite its name, organosilicate glass consists of a silicon-oxygen framework to which some organic functional groups, such as methyl groups, are covalently attached. Thus, the structural framework of organosilicate glass is predominantly characterized by inorganic silicon-oxygen bonds, which determine predominant characteristics of the physical and chemical properties (such as high thermal stability, low electrical conductivity, and mechanical robustness) which are physical properties of inorganic networks. Consequently, organosilicate glass is classified as an inorganic material.

In one embodiment, the topmost dielectric layer selected from the dielectric material layers 460 may comprise an inorganic material that is conducive to dielectric-to-dielectric bonding, such as silicon oxide-to-silicon oxide bonding. In one embodiment, the topmost dielectric layer selected from the dielectric material layers 460 may comprise a first silicon oxide layer consisting essentially of silicon oxide.

Bonding-level metallic structures (488, 486) compatible with metal-to-metal bonding, such as copper-to-copper bonding, and may be formed within the topmost dielectric layer selected from the dielectric material layers 460. The bonding-level metallic structures (488, 486) that are formed in the topmost dielectric layer comprise on-interposer bonding pads 488 and bonding-level metallic edge seal structures 486. The combination of the dielectric substrate 410, the optional dielectric stress relief layer 450, the interconnect-level metal structures (480, 486), and the bonding-level metallic structures (488, 486) are subsequently used to provide dielectric interposers, and thus, the bonding pads that are formed within the topmost dielectric layer selected from the dielectric material layers 460 are referred to as on-interposer bonding pads 488.

The on-interposer bonding pads 488 may be configured for metal-to-metal bonding, such as copper-to-copper bonding. As such, the physically exposed top surfaces of the on-interposer bonding pads 488 may be formed entirely within a horizontal plane. In one embodiment, the topmost dielectric layer selected from the dielectric material layers 460 may be configured for dielectric-to-dielectric bonding such as silicon oxide-to-silicon oxide bonding. In this embodiment, the top surfaces of the on-interposer bonding pads 488 may be located within a horizontal plane including the top surface of the topmost dielectric layer selected from the dielectric material layers 460. The bonding-level metallic edge seal structures 486 may have an annular configuration, and may laterally enclose a set of all on-interposer bonding pads 488 within a respective unit area UA. In one embodiment, the bottom surface of each bonding-level metallic edge seal structure 486 may contact the topmost surface of a respective underlying interconnect-level metallic edge seal structure 482. Generally, the bonding-level metallic edge seal structures 486 and the interconnect-level metallic edge seal structures 482 may have the same shape as the underlying substrate metallic edge seal structures 430 except for the modulation in the horizontal cross-sectional shapes caused by the changes in the widths of the metal lines or metal via structures.

The on-interposer bonding pads 488 and the bonding-level metallic edge seal structures 486 may be formed by patterning pad cavities and moat trenches in the topmost level of the dielectric material layers 460. The pad cavities in the topmost level of the dielectric material layers 460 may have the pattern of bonding pads to be subsequently performed. The moat trenches in the topmost level of the dielectric material layers 460 may have the same pattern as the moat trenches 429 that are formed at the processing steps described with reference to FIGS. 2A-2E. At least one metallic fill material may be deposited in the pad cavities and the moat trenches and over the topmost level of the dielectric material layers 460. A planarization process that removes portions of the at least one metallic fill material from above the horizontal plane including the topmost surface of the dielectric material layers 460 may be performed. Remaining portions of the at least one metallic fill material in the pad cavities comprise the on-interposer bonding pads 488. Remaining portions of the at least one metallic fill material in the moat trenches comprise the bonding-level metallic edge seal structures 486. The on-interposer bonding pads 488 are electrically connected to the arrays of through-dielectric via structures 420 through a subset of the interconnect-level metal structures (480, 482) (such as the metal interconnect structures 480). Each of the bonding-level metallic edge seal structures 486 contacts a respective one of the interconnect-level metallic edge seal structures 482.

In embodiments that include the dielectric stress relief layer 450, the dielectric stress relief layer 450 comprises a dielectric material having a lower Young's modulus than any material in the dielectric material layers 460. In one embodiment, the dielectric stress relief layer 450 may be disposed between the dielectric substrate 410 and the dielectric material layers 460, and a subset of the interconnect-level metal structures (480, 482) vertically extends through the dielectric stress relief layer 450. Silicon oxide has a Young's modulus in a range from 70 GPa to 75 GPa. The dielectric materials that may be used for the dielectric stress relief layer 450 may be selected from organosilicate glass (OSG) having a Young's modulus in a range from 3 GPa to 10 GPa, porous organosilicate glass (porous OSG) having a Young's modulus in a range from 1 GPa to 5 GPa, silicon oxycarbide (SiOC) having a Young's modulus in a range from 4 GPa to 10 GPa, and polymer materials such as polyimide (PI) having a Young's modulus in a range from 2 GPa to 8 GPa, benzocyclobutene (BCB) having a Young's modulus in a range from 2 GPa to 6 GPa, and polytetrafluoroethylene (PTFE) having a Young's modulus in a range from 0.5 GPa to 1 GPa. The thickness of the dielectric stress relief layer 450 may be in a range from 50 nm to 1,000 nm, such as from 100 nm to 500 nm, although lesser or greater thicknesses may also be used. The dielectric stress relief layer 450, if present, deforms more easily than the material of the dielectric substrate 410 or the materials of the dielectric material layers 460, and protects the dielectric substrate 410 and the dielectric material layers 460 be absorbing external stress. A subset of the interconnect-level metal structures (480, 482) is formed through the dielectric stress relief layer 450.

Generally, dielectric material layers 460 and interconnect-level metal structures (480, 482) may be formed over the dielectric substrate 410, and a subset of the interconnect-level metal structures (480, 482), such as the metal interconnect structures 480, are electrically connected to the array of through-dielectric via structures 420. The topmost dielectric material layer selected from the dielectric material layers 460 comprises a first silicon oxide layer, and the on-interposer bonding pads 488 are laterally surrounded by the first silicon oxide layer.

Within each unit area UA, at least one interconnect-level metallic edge seal structure 482 may be formed through the dielectric material layers 460 directly on a respective one of the at least one substrate metallic edge seal structure 430. Within each unit area UA, at least one interconnect-level metallic edge seal structure 482 vertically extends through the dielectric material layers 460. The at least one interconnect-level metallic edge seal structure 482 may be located on a respective one of the at least one substrate metallic edge seal structure 430, and may laterally surround the metal interconnect structures 480.

The combination of the dielectric substrate 410 and the dielectric material layers 460 and structures formed therein constitute an interposer wafer 400W including a two-dimensional array of dielectric interposers 400 that are adjoined to one another. Each dielectric interposer 400 is an interposer including a dielectric substrate 410, and is located within a respective unit area UA.

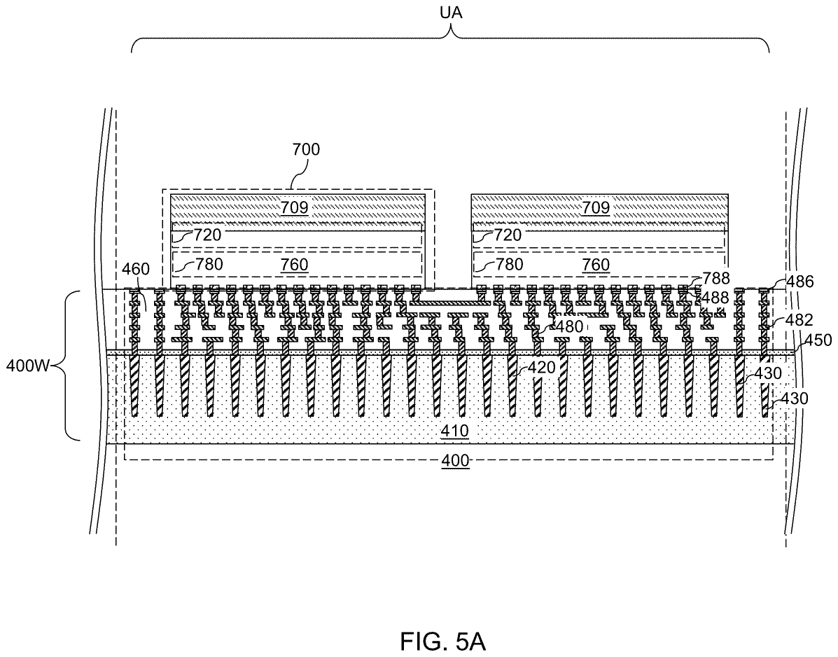

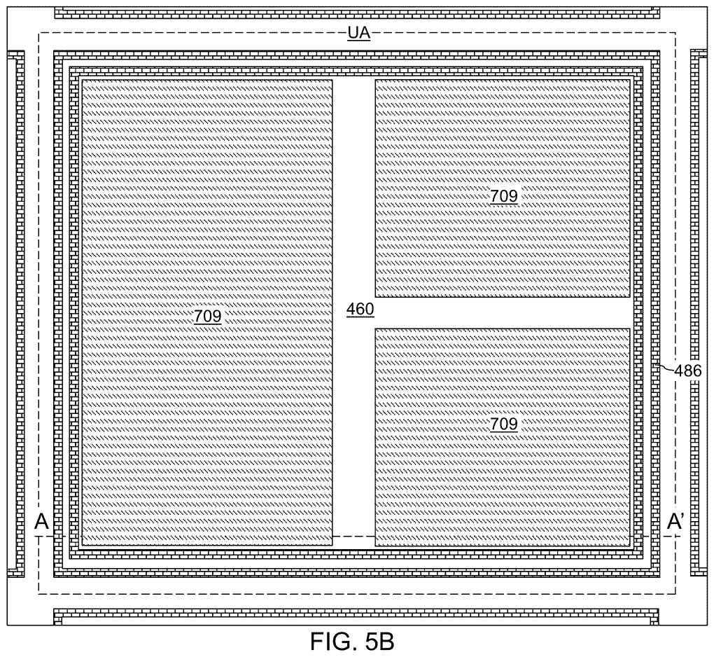

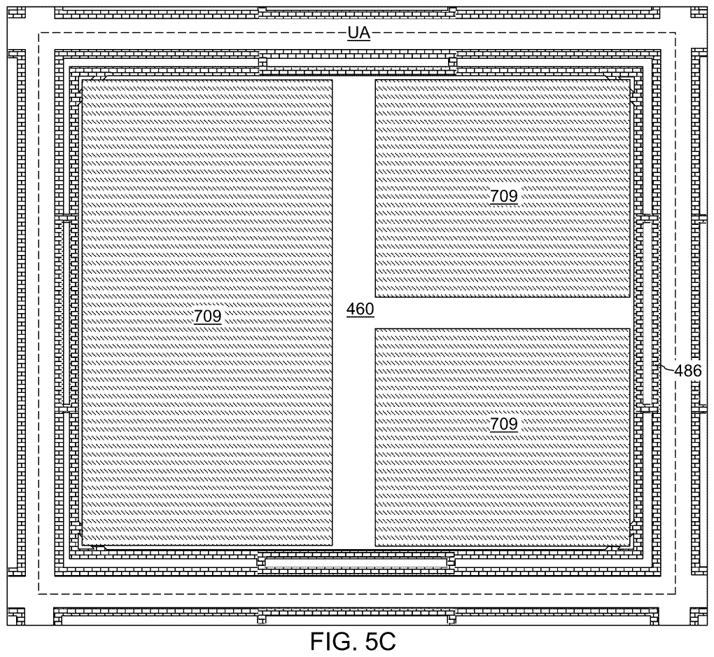

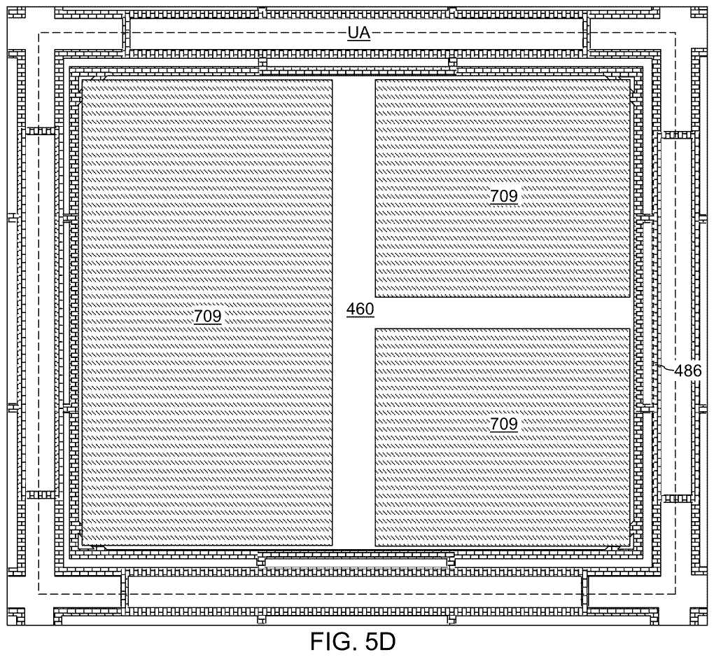

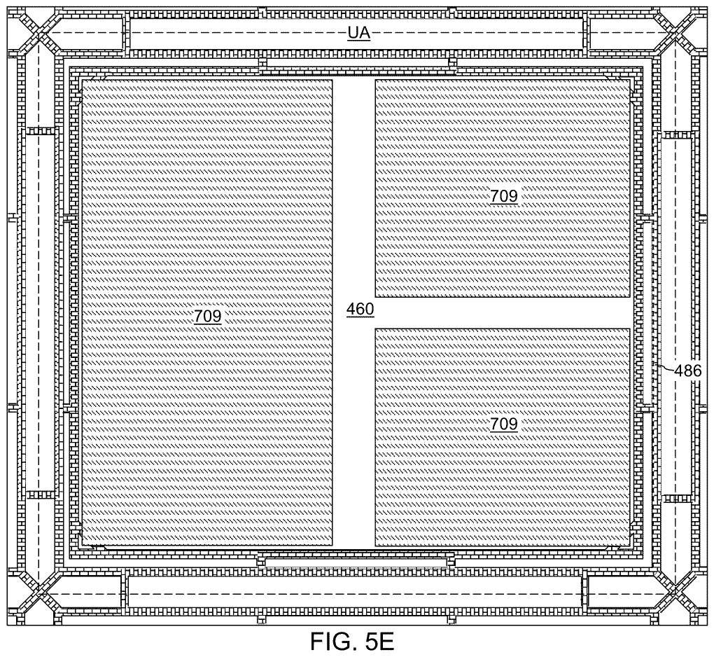

FIG. 5A is a vertical cross-sectional view of a region of a bonded assembly of the interposer wafer 400W and semiconductor dies 700 according to an embodiment of the present disclosure. FIG. 5B is a top-down view of the region of the bonded assembly of FIG. 5A. The vertical plane A-A′ is the cut plane of the vertical cross-sectional view of FIG. 5A. FIG. 5C is a top-down view of a first alternative configuration of the bonded assembly of FIGS. 5A and 5B. FIG. 5D is a top-down view of a second alternative configuration of the bonded assembly of FIGS. 5A and 5B. FIG. 5E is a top-down view of a third alternative configuration of the bonded assembly of FIGS. 5A and 5B.

Referring to FIGS. 5A-5E, a set of at least one semiconductor die 700 may be disposed over a respective dielectric interposer 400 within each unit area UA. Each semiconductor die 700 may comprise a respective semiconductor die substrate 709, a respective set of semiconductor devices 720 located in, on, or over, the respective semiconductor die substrate 709, and respective in-die dielectric material layers 760 containing in-die metal interconnect structures 780 and on-die bonding pads 788. In one embodiment, the respective semiconductor die substrate 709 may be a silicon substrate, and the respective set of semiconductor dies 700 may comprise various semiconductor devices known in the art such as field effect transistors. The in-die dielectric material layers 760 may comprise inorganic interlayer dielectric (ILD) materials such as dielectric oxide or dielectric nitride. The in-die metal interconnect structures 780 may comprise metal via structures and metal line structures that are interconnected to the semiconductor devices 720 and to one another. The on-die bonding pads 788 may be formed in a topmost dielectric material layer selected from the in-die dielectric material layers 760, and may be electrically connected to the in-die metal interconnect structures 780. In one embodiment, top surfaces of the on-die bonding pads 788 may be formed within a horizontal plane including a top surface of the topmost dielectric material layer selected from the in-die dielectric material layers 760.

Each set of at least one semiconductor die 700 may include a single semiconductor die 700, or may comprise a plurality of semiconductor dies 700. For example, each set of at least one semiconductor die 700 may include at least one system-on-chip (SoC) die and/or at least one memory die. Each SoC die may comprise an application processor die, a central processing unit die, or a graphic processing unit die. In one embodiment, the at least one memory die may comprise a high bandwidth memory (HBM) die that includes a vertical stack of static random access memory dies. In one embodiment, the at least one semiconductor die may include at least one system-on-chip (SoC) die and at least one high bandwidth memory (HBM) die. Each HBM die may comprise a vertical stack of static random access memory (SRAM) dies that are interconnected to one another through arrays of microbumps and are laterally surrounded by a respective molding material enclosure frame.

Within each unit area UA, each of the at least one semiconductor die 700 comprises a respective set of on-die bonding pads 788 that is bonded to a respective subset of the array of on-interposer bonding pads 488 in the unit area UA via metal-to-metal bonding. Specifically, each of the at least one semiconductor die 700 may be attached to the on-interposer bonding pads 488 by inducing metal-to-metal bonding between mating pairs of the on-die bonding pads 788 and the on-interposer bonding pads 488. In one embodiment, within each unit area UA, a topmost dielectric material layer selected from the dielectric material layers 460 comprises a first silicon oxide layer, and the on-interposer bonding pads 488 in the unit area UA are laterally surrounded by the first silicon oxide layer. In one embodiment, each of the at least one semiconductor die 700 comprises a respective second silicon oxide layer that laterally surrounds a respective subset of the on-die bonding pads 788, and is bonded to a respective surface segment of the first silicon oxide layer via oxide-to-oxide bonding.

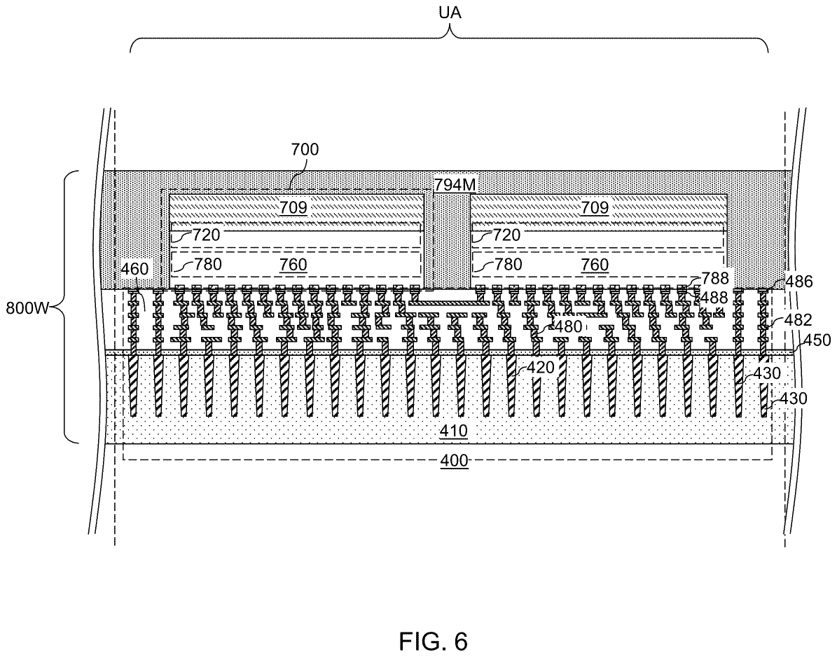

Referring to FIG. 6, a die frame material may be applied over the interposer wafer 400W and the array of sets of at least one semiconductor die 700 that is bonded to the array of dielectric interposers 400 in the interposer wafer 400W. In one embodiment, the die frame material includes an epoxy-containing compound that may be hardened (i.e., cured) to provide a dielectric material portion having sufficient stiffness and mechanical strength. In this embodiment, the die frame material may include epoxy resin, hardener, silica (as a filler material), and other additives. The die frame material may be provided in a liquid form or in a solid form depending on the viscosity and flowability. Liquid die frame material typically provides better handling, good flowability, less voids, better fill, and less flow marks. Solid die frame material typically provides less cure shrinkage, better stand-off, and less die drift. A high filler content (such as 85% in weight) within a die frame material may shorten the time in mold, lower the mold shrinkage, and reduce the mold warpage. Uniform filler size distribution in the die frame material may reduce flow marks, and may enhance flowability.

Alternatively, the die frame material may comprise an inorganic material that may be cured subsequently planarized. For example, the die frame material may comprise spin-on oxide, which may be spin-coated and subsequently cured to form a silicon oxide matrix.

A die frame matrix 794M may be formed by the die frame material. The die frame matrix 794M may fill remaining gaps between neighboring pairs of semiconductor dies 700. The die frame matrix 794M may cover each of the semiconductor dies 700, and may have a top surface that continuously extends over each of the semiconductor dies 700. Each portion of the die frame matrix 794M located within a respective unit area UA constitutes a dielectric die frame. Thus, the die frame matrix 794M comprises a two-dimensional periodic array of dielectric die frames that are adjoined to one another. Generally, the dielectric die frames comprise a material selected from a molding compound material and an inorganic dielectric material. The combination of the interposer wafer 400W, the array of semiconductor dies 700, and the die frame matrix 794M constitutes a reconstituted wafer 800W.

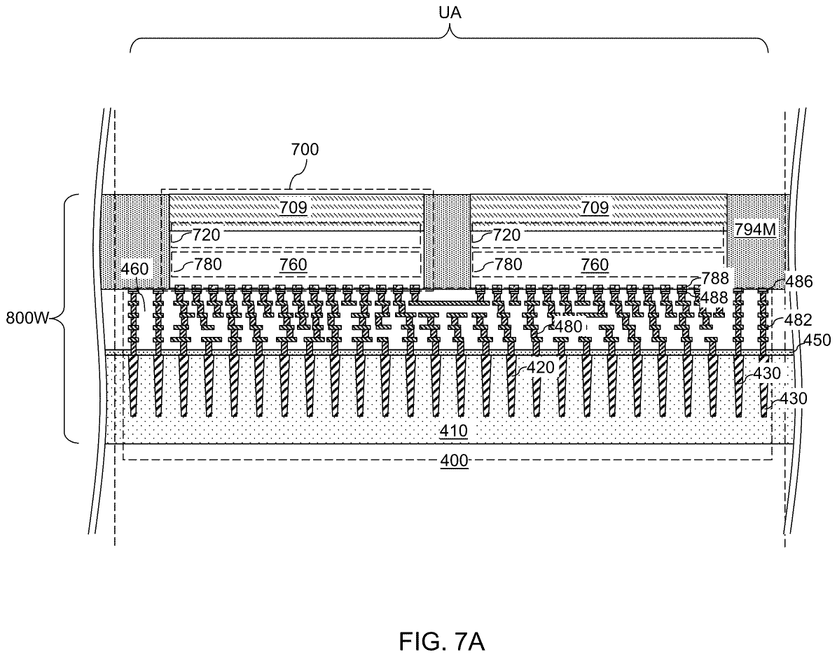

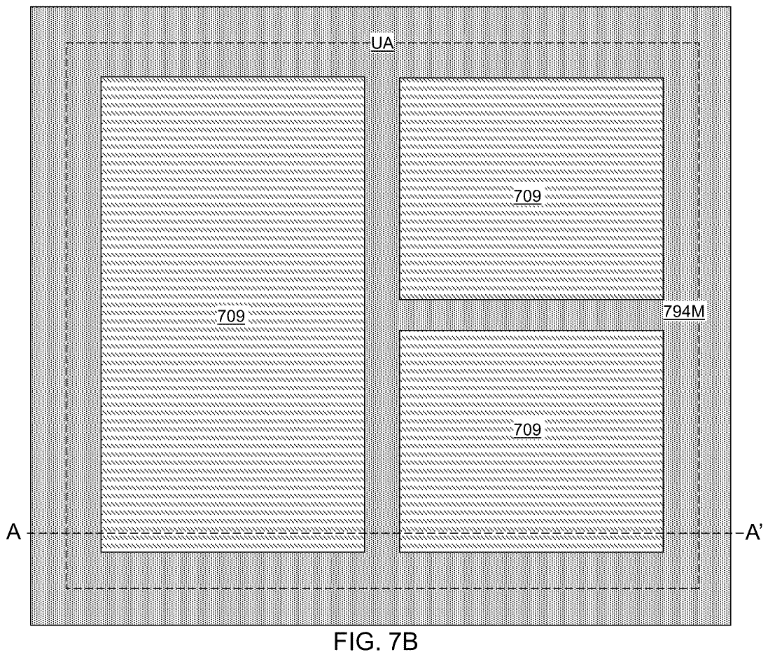

Referring to FIGS. 7A and 7B, a polishing process may be performed to remove a horizontally-extending portion of the die frame matrix 794M from above the horizontal plane including the top surfaces of the thinnest semiconductor dies 700. For example, a chemical mechanical polishing (CMP) process may be performed to remove the horizontally-extending portion of the die frame matrix 794M and optionally to remove topmost portions of the semiconductor dies 700. All physically exposed top surfaces of the semiconductor dies 700 and a polished horizontal surface of the die frame matrix 794M may be formed within a two-dimensional horizontal plane.

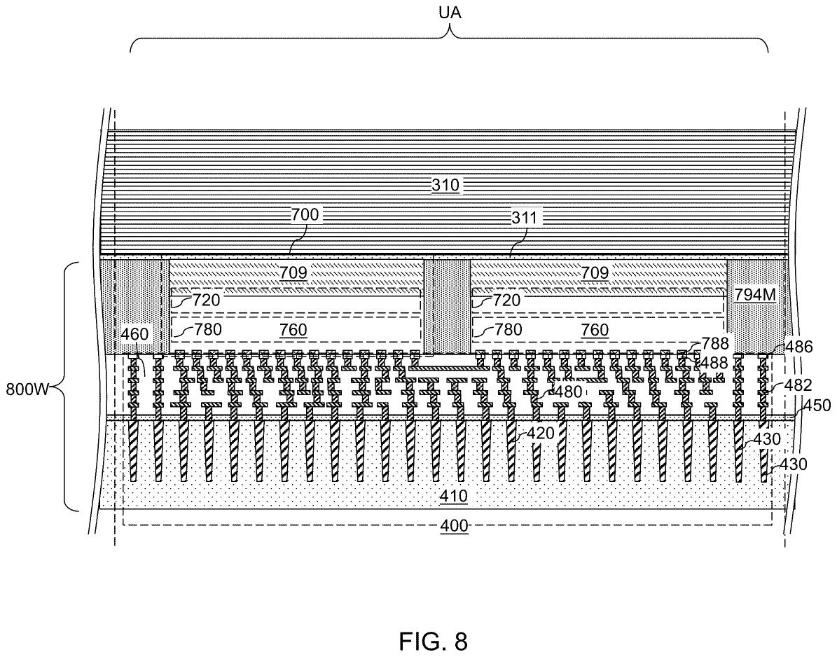

Referring to FIG. 8, a carrier wafer 310 may be attached to the reconstituted wafer 800W. An adhesive layer 311 may be applied to the top surfaces of the semiconductor dies 700 and to the top surface of the die frame matrix 794M. A carrier wafer 310 may be attached to the adhesive layer 311. In one embodiment, the carrier wafer 310 may include an optically transparent substrate such as a glass substrate or a sapphire substrate. The lateral dimensions of the carrier wafer 310 may be the same as the lateral dimensions of the reconstituted wafer 800W. In one embodiment, the horizontal cross-sectional shape of the carrier wafer 310 may be the same as the horizontal cross-sectional shape of the reconstituted wafer 800W. The thickness of the carrier wafer 310 may be in a range from 500 microns to 2,000 microns, although lesser and greater thicknesses may also be used. In one embodiment, the adhesive layer 311 may be a light-to-heat conversion (LTHC) layer. Alternatively, the adhesive layer 311 may include a thermally decomposing adhesive material.

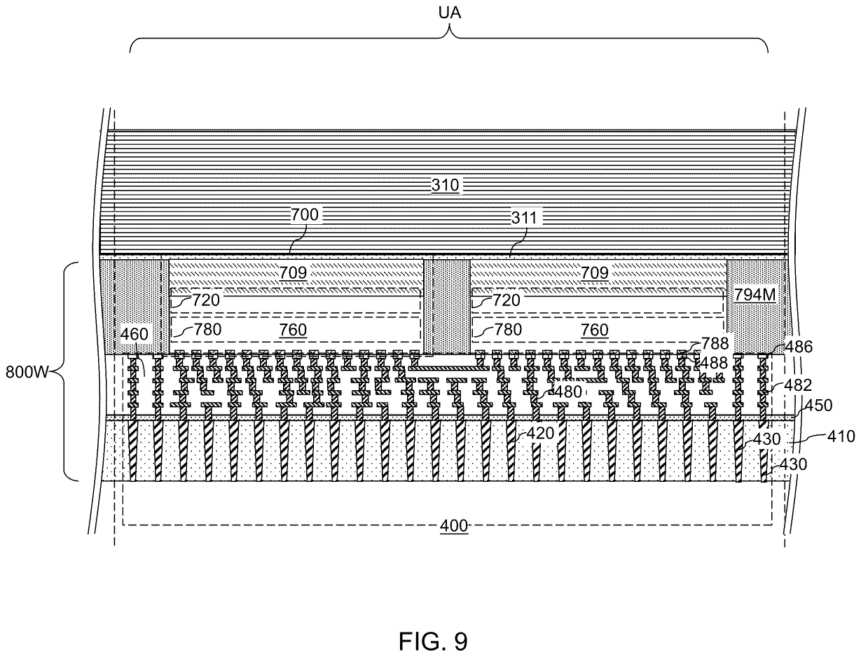

Referring to FIG. 9, a backside polishing process may be performed to remove the backside of the dielectric substrate 410. The dielectric substrate 410 may be removed by grinding, polishing, an anisotropic etch process, an isotropic etch process, or a combination thereof. In one embodiment, a plurality of dielectric removal processes may be sequentially performed to remove the backside portion of the dielectric substrate 410 until the bottom surfaces of the TSV structures 420 are exposed. The TSV structures 420 may be used as polishing stop structures and/or etch stop structures. In one embodiment, the plurality of dielectric removal processes may comprise a terminal process that uses a chemical mechanical polishing process after which bottom surfaces of the TSV structures 420 may be exposed.

Generally, bottom end surfaces of the through-dielectric via structures 420 are exposed upon thinning of the backside portion of the dielectric substrate 410. Further, bottom end surfaces of the substrate metallic edge seal structures 430 may be exposed upon thinning of the backside portion of the dielectric substrate 410. In one embodiment, each of the through-dielectric via structures 420 comprises a respective straight sidewall that extends from a front surface of the dielectric substrate 410 to a backside surface of the dielectric substrate 410. In one embodiment, all sidewalls of the through-dielectric via structures 420 are in direct contact with the dielectric substrate 410.

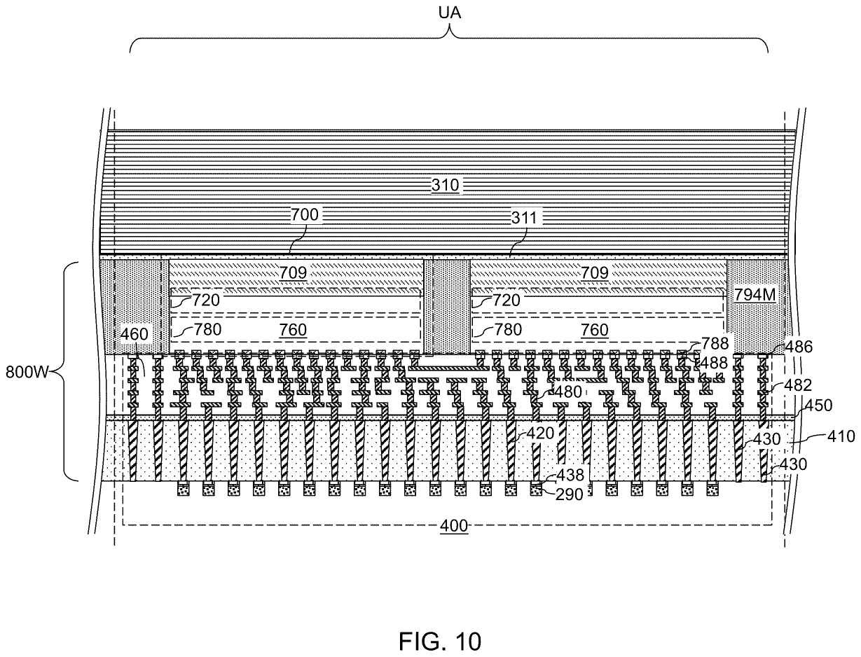

Referring to FIG. 10, backside bonding pads 438 and solder material portions 290 may be formed on the physically exposed bottom surfaces of the through-dielectric via structures 420. In an illustrative example, a metallic material layer stack including underbump metallurgy (UBM) material layer may be deposited on the bottom surfaces of the through-dielectric via structures 420 and on the backside surface of the dielectric substrate 410. A solder material layer may be deposited on the metallic material layer stack. A photoresist layer (not shown) may be applied and lithographically patterned on the solder material layer, and the pattern in the photoresist layer may be transferred through the solder material layer and the metallic material layer stack to form an array of solder material portions 290 and an array of backside bonding pads 438 on each dielectric interposer 400. The photoresist layer may be subsequently removed, for example, by ashing.

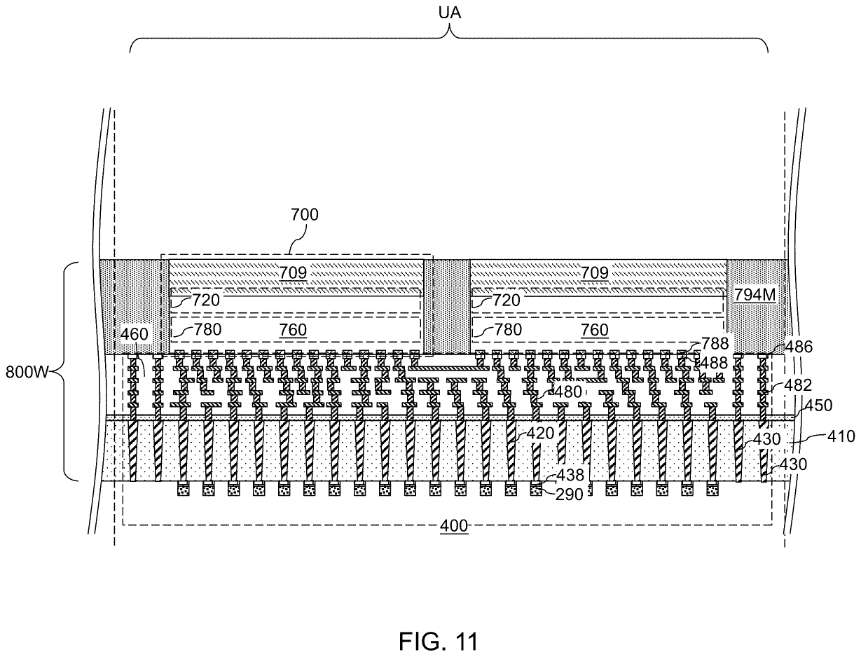

Referring to FIG. 11, the carrier wafer 310 may be detached from the reconstituted wafer 800W. In some embodiments, the carrier wafer 310 and the adhesive layer 311 may be removed by backside grinding. Alternatively, the carrier wafer 310 includes an optically transparent material and the adhesive layer 311 comprises a light-to-heat conversion material, and irradiation through the carrier wafer 310 may be used to detach the carrier wafer 310. If the adhesive layer 311 comprises a thermally decomposable adhesive material, an anneal process or a laser irradiation may be used to detach the carrier wafer 310. A suitable clean process may be performed to remove residual portions of the adhesive layer 311. The reconstituted wafer 800W includes a two-dimensional array of dielectric interposers 400, and further includes a two-dimensional array of sets of at least one semiconductor die 700 that are bonded to a respective dielectric interposer 400.

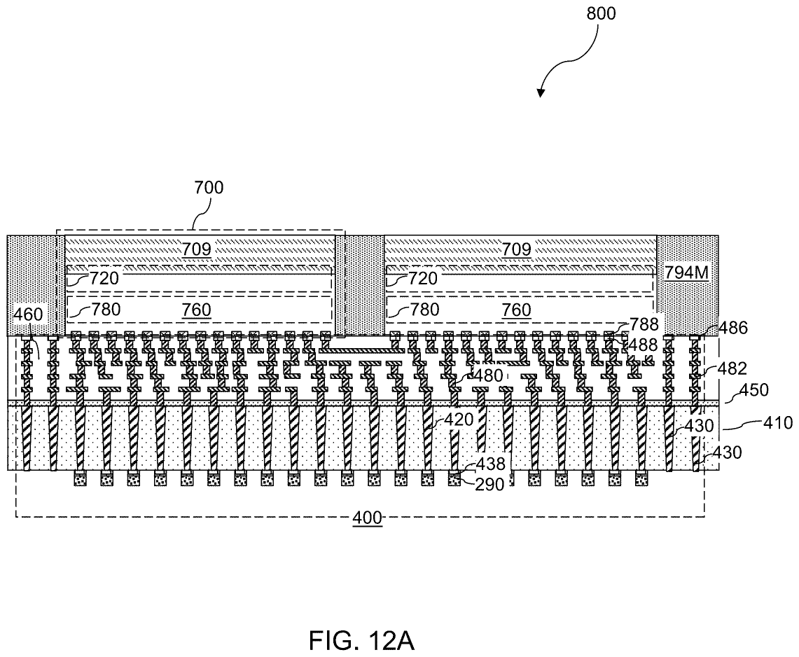

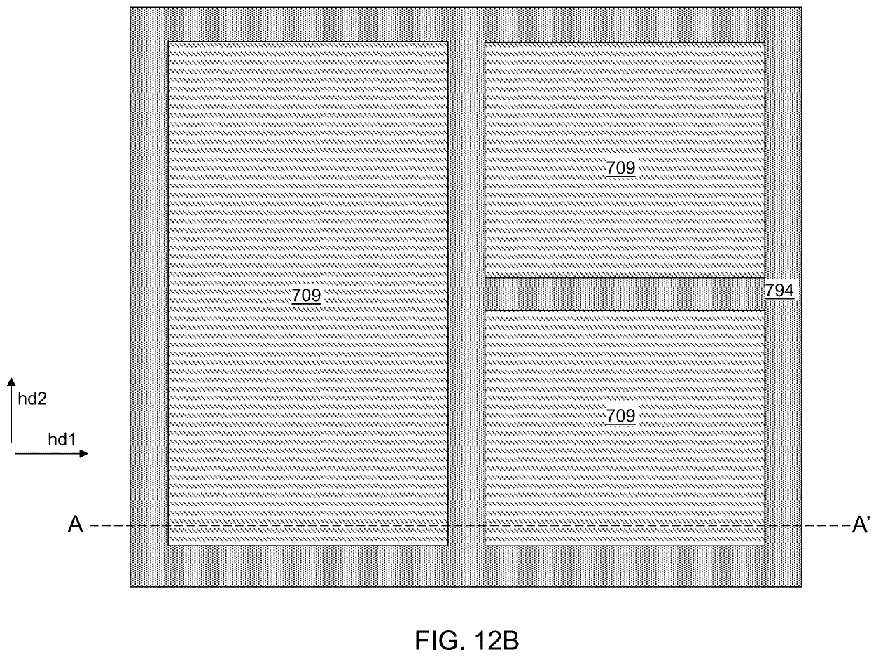

Referring to FIGS. 12A and 12B, the reconstituted wafer 800W may be diced along dicing channels by performing a dicing process. The dicing channels correspond to the boundaries between neighboring pairs of unit areas UA. Each diced unit from the reconstituted wafer comprises a composite die 800. Each diced portion of the die frame matrix 794M constitutes a dielectric die frame 794.

The diced portions of the reconstituted wafer comprise composite dies 800. Each composite die 800 comprises at least one semiconductor die 700, a dielectric interposer 400, and a dielectric die frame 794. Generally, a dielectric die frame 794 may be formed around at least one semiconductor die 700 within each composite die 800. In one embodiment, the dielectric die frame 794 laterally surrounds the at least one semiconductor die 700 and contacts a horizontal surface of a topmost one of the dielectric material layers 460.

Generally, a composite die 800 may have a rectangular shape, and may comprise a pair of first sidewalls that laterally extend along a first horizontal direction hd1 and a pair of second sidewalls that laterally extend along a second horizontal direction hd2 that is perpendicular to the first horizontal direction hd1. In some embodiments, the at least one semiconductor die 700 that is attached to a dielectric interposer 400 may be a plurality semiconductor dies 700. In the illustrated configuration of FIGS. 12A and 12B, the at least one semiconductor die 700 comprises three semiconductor dies 700.

In one embodiment, a subset of the substrate metallic edge seal structures 430 comprises wall portions and lateral protrusion portions 440 that extend outward from the wall portions. Each of the lateral protrusion portions 440 may be formed within the volume of a respective connecting cavity 439. In this embodiment, the dielectric material layers 460, the dielectric substrate 410, and a subset of the lateral protrusion portions 440 may be diced during the dicing process. Generally, a composite die 800 comprises a diced portion of the dielectric substrate 410, an array of through-dielectric via structures 420, a diced portion of the dielectric material layers 460, a subset of the interconnect-level metal structures (480, 482), and at least one semiconductor die 700. In embodiments in which the lateral protrusion portions 440 of the substrate metallic edge seal structures 430 are cut through during the dicing process, sidewalls of remaining portions of the lateral protrusion portions 440 may be physically exposed in each composite die 800.

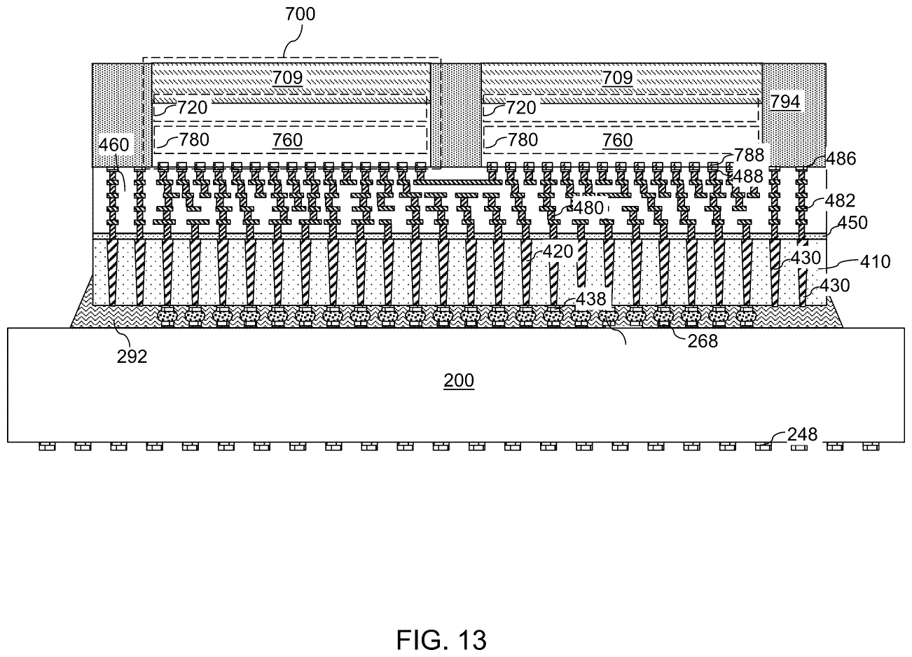

Referring to FIG. 13, a packaging substrate 200 may be bonded to the composite die 800. The packaging substrate 200 may be a cored packaging substrate including a core substrate, or a coreless packaging substrate that does not include a package core. Alternatively, the packaging substrate 200 may include a system-on-integrated packaging substrate (SoIS) including redistribution layers, dielectric interlayers, and/or at least one embedded interposer (such as a dielectric interposer). Such a system-integrated packaging substrate may include layer-to-layer interconnections using solder material portions, microbumps, underfill material portions (such as molded underfill material portions), and/or an adhesion film. In some embodiments, the packaging substrate 200 may comprise a system-on-integrated substrate package including a glass epoxy plate with an array of through-plate holes. An array of through-core via structures (not illustrated) including a metallic material may be provided in the through-plate holes. Each through-core via structure may, or may not, include a cylindrical hollow therein. Optionally, dielectric liners (not illustrated) may be used to electrically isolate the through-core via structures from the core substrate.

Substrate bonding pads 268 may be provided on one side of the packaging substrate 200, and board-side bonding pads 248 may be provided on another side of the packaging substrate 200. The composite die 800 may be attached to the packaging substrate 200 using the second solder material portions, which are herein referred to interposer-substrate-bonding (ISB) solder material portions 290. Specifically, each of the ISB solder material portions 290 may be bonded to a respective one of the substrate bonding pads 268 and to a respective one of the backside bonding pads 438 located on the dielectric interposer 400. A reflow process may be performed to reflow the ISB solder material portions 290 such that each ISB solder material portion 290 may be bonded to a respective one of the substrate bonding pads 268 and to a respective one of the backside bonding pads 438.

An underfill material may be applied into a gap between the dielectric interposer 400 and the packaging substrate 200. The underfill material may comprise any underfill material known in the art. An underfill material portion may be formed around the ISB solder material portions 290 in the gap between the dielectric interposer 400 and the packaging substrate 200. This underfill material portion is herein referred to as an interposer-substrate underfill material portion 292, or as an IP underfill material portion 292.

Generally, a composite die 800 may be attached to a packaging substrate 200 using an array of solder material portions 290 that is bonded to that is bonded to backside bonding pads 438 that are formed on bottom end surfaces of the through-substrate via structures 420 within the composite die 800, and is bonded to bonding structures (such as the substrate bonding pads 268) on the packaging substrate 200. Thus, the array of solder material portions 290 is disposed between the through-dielectric via structures 420 and the bonding structures on the packaging substrate 200.

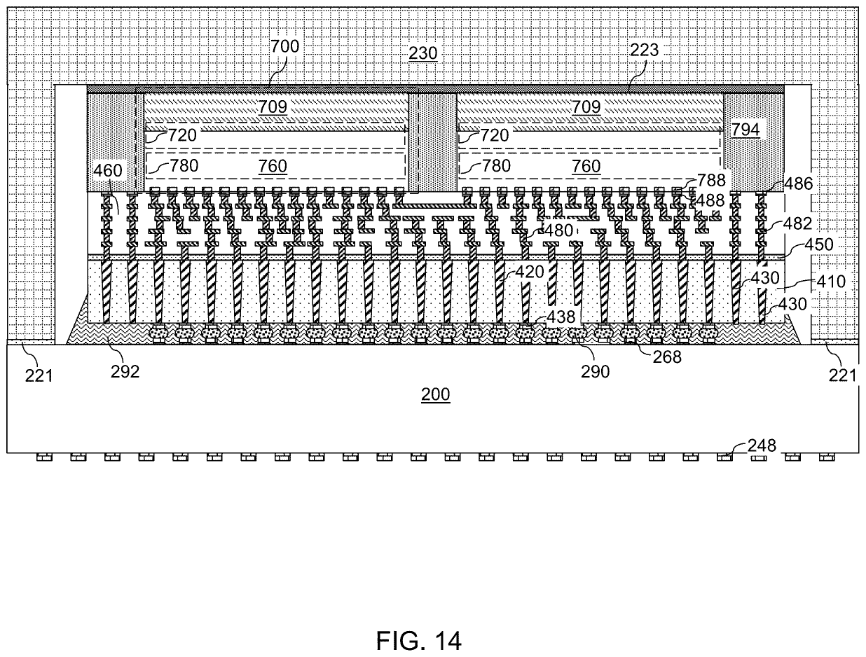

Referring to FIG. 14, a lid structure 230 (which is also referred to as a stabilization structure or a stiffener ring) may be attached to a peripheral portion of the top surface of the packaging substrate 200, for example, through an adhesive layer 221. A thermal interface material layer 223 may be applied on the physically exposed top surface of the composite die 800. The bottom surface of a horizontally-extending portion of the lid structure 230 that overlies the composite die 800 may contact the thermal interface material layer 223. In this embodiment, the thermal interface material layer 223 may provide heat conduction paths between the at least one semiconductor die 700 and the lid structure 230.

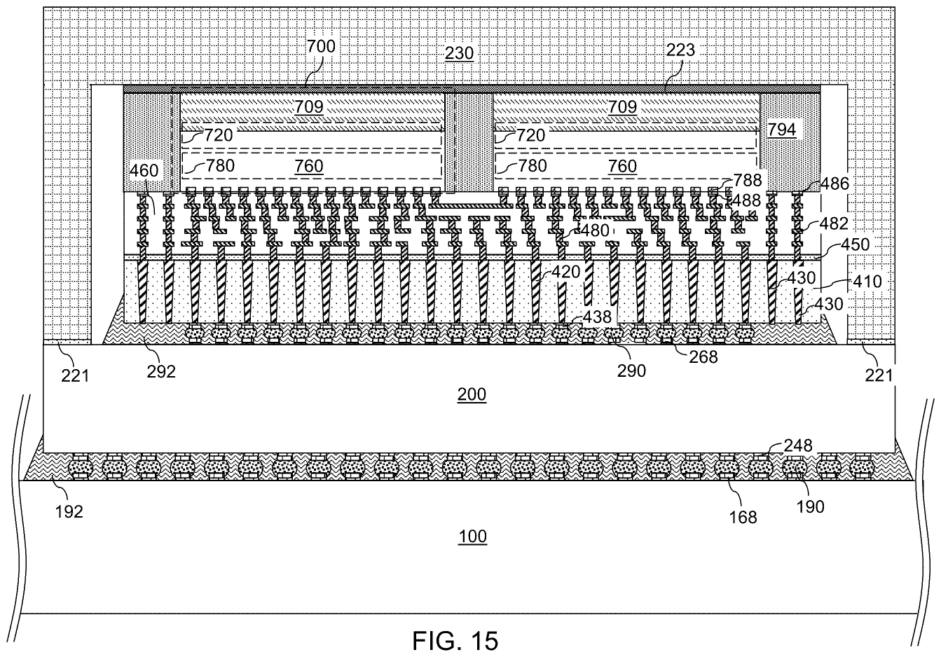

Referring to FIG. 15, a printed circuit board (PCB) 100 including a PCB substrate and PCB bonding pads 168 may be provided. The PCB 100 includes a printed circuitry (not shown) at least on one side of the PCB substrate. An array of solder joints 190 may be used to bond the array of board-side bonding pads 248 to the array of PCB bonding pads 168. The solder joints 190 may be formed by disposing an array of solder balls between the array of board-side bonding pads 248 and the array of PCB bonding pads 168, and by reflowing the array of solder balls. An additional underfill material portion, which is herein referred to as a board-substrate underfill material portion 192 or a BS underfill material portion 192, may be formed around the solder joints 190 by applying and shaping an underfill material. The packaging substrate 200 is attached to the PCB 100 through the array of solder joints 190.

Generally, the diced portion of the dielectric substrate 410 within each composite die 800, which is referred to as a dielectric substrate 410 of the composite die 800, may have any configuration described with reference to FIGS. 2B-2E, 3B-3E, 4B-4E, and 5B-5E.

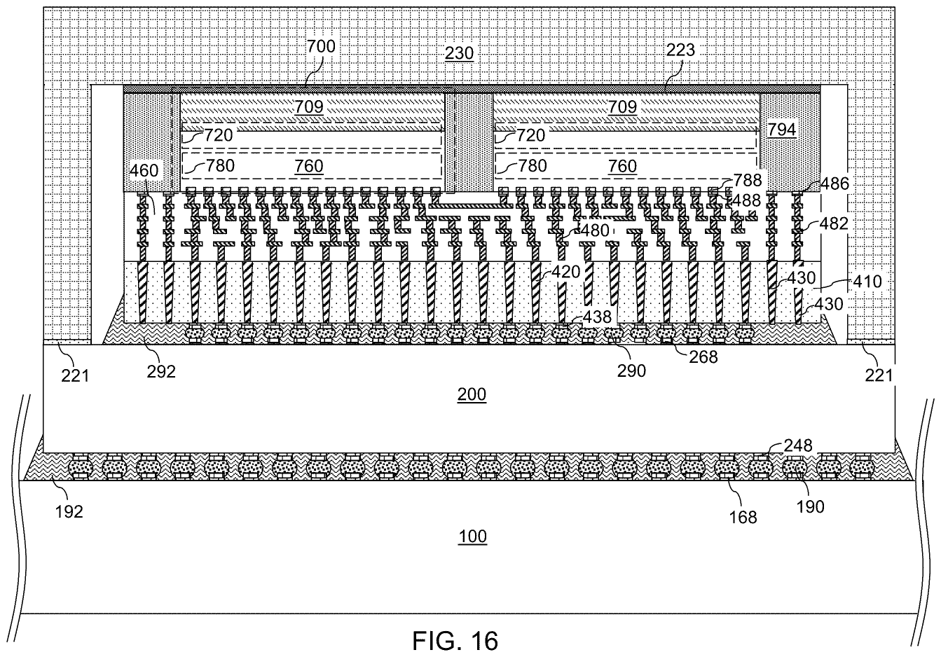

Referring to FIG. 16, a first alternative configuration of the assembly of the composite die 800, the packaging substrate 200, the lid structure, and the printed circuit board according to an embodiment of the present disclosure is illustrated. The first alternative configuration of the assembly may be derived from the assembly described with reference to FIG. 15 by omitting formation of the dielectric stress relief layer 450.

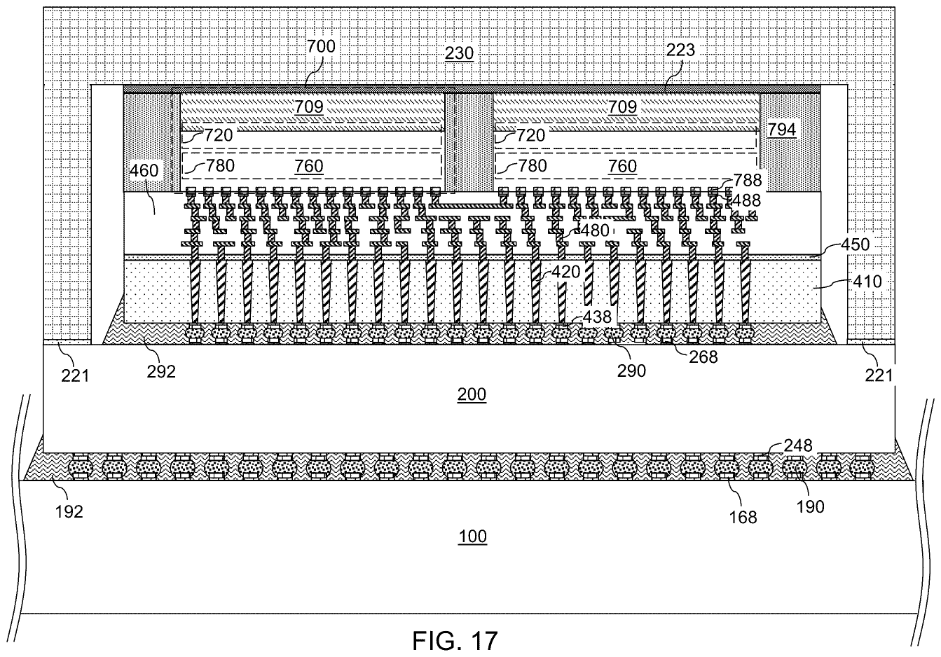

Referring to FIG. 17, a second alternative configuration of the assembly of the composite die 800, the packaging substrate 200, the lid structure, and the printed circuit board according to an embodiment of the present disclosure is illustrated. The second alternative configuration may be derived from the assembly illustrated in FIG. 15 or from the assembly illustrated in FIG. 16 by omitting one of more structural elements selected from at least one substrate metallic edge seal structure 430, at least one interconnect-level metallic edge seal structure 482, and at least one bonding-level metallic edge seal structure 486. While FIG. 17 illustrates an embodiment in which all of substrate metallic edge seal structures 430, interconnect-level metallic edge seal structures 482, and bonding-level metallic edge seal structures 486 are omitted, embodiments are expressly contemplated herein in which only a subset of the substrate metallic edge seal structures 430, the interconnect-level metallic edge seal structures 482, and the bonding-level metallic edge seal structures 486 are omitted.

Referring collectively to FIGS. 1A-16 and according to various embodiments of the present disclosure, a device structure is provided, which comprises: an array of through-dielectric via structures 420 vertically-extending through a dielectric substrate 410, wherein each of the through-dielectric via structures 420 comprises a respective straight sidewall that extends from a front surface of the dielectric substrate 410 to a backside surface of the dielectric substrate 410; dielectric material layers 460 and interconnect-level metal structures (480, 482) located over the dielectric substrate 410; on-interposer bonding pads 488 located at a topmost level of the dielectric material layers 460, wherein the on-interposer bonding pads 488 are electrically connected to the array of through-dielectric via structures 420 through the interconnect-level metal structures (480, 482); and at least one semiconductor die 700 attached to the on-interposer bonding pads 488.

In one embodiment, all sidewalls of the through-dielectric via structures 420 are in direct contact with the dielectric substrate 410. In one embodiment, each of the at least one semiconductor die 700 comprises on-die bonding pads 788 that are bonded to a respective one of the on-interposer bonding pads 488 via metal-to-metal bonding.

In one embodiment, the device structure further comprises a dielectric stress relief layer 450 comprising a dielectric material having a lower Young's modulus than any material in the dielectric material layers 460 and disposed between the dielectric substrate 410 and the dielectric material layers 460. A subset of the interconnect-level metal structures (480, 482) vertically extends through the dielectric stress relief layer 450.

In one embodiment, the device structure further comprises: at least one substrate metallic edge seal structure 430 vertically extending through the dielectric substrate 410 and laterally surrounding the array of through-dielectric via structures 420; and at least one interconnect-level metallic edge seal structure 482 vertically extending through the dielectric material layers 460, located on a respective one of the at least one substrate metallic edge seal structure 430, and laterally surrounding the interconnect-level metal structures (480, 482).

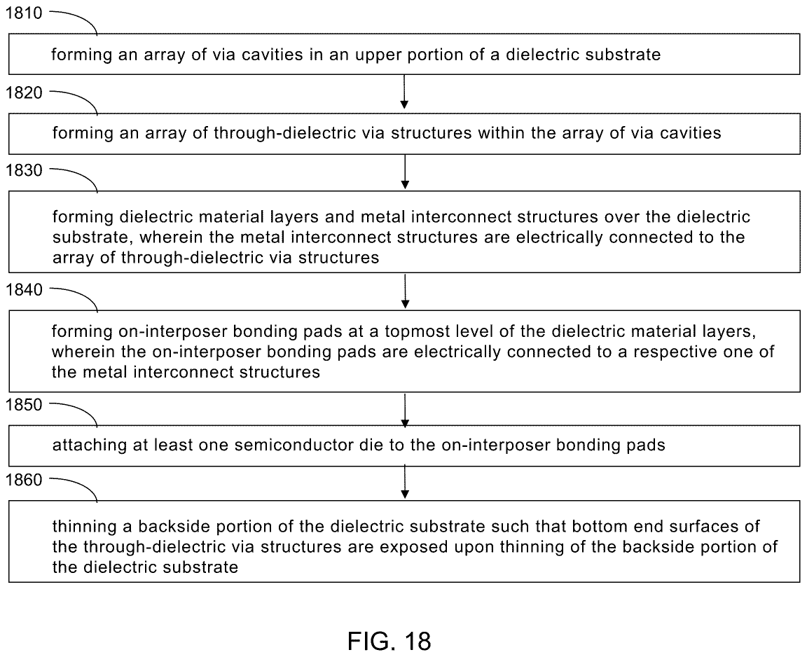

FIG. 18 is a first flowchart illustrating steps for forming a device structure according to an embodiment of the present disclosure.

Referring to step 1810 and FIGS. 1A-2E, an array of via cavities 419 may be formed in an upper portion of a dielectric substrate 410.

Referring to step 1820 and FIGS. 3A-3E, an array of through-dielectric via structures 420 may be formed within the array of via cavities 419.

Referring to step 1830 and FIGS. 4A-4E, dielectric material layers 460 and metal interconnect structures 480 may be formed over the dielectric substrate 410. The metal interconnect structures 480 are electrically connected to the array of through-dielectric via structures 420.

Referring to step 1840 and FIGS. 4A-4E, on-interposer bonding pads 488 may be formed at a topmost level of the dielectric material layers 460. The on-interposer bonding pads 488 are electrically connected to a respective one of the metal interconnect structures 480.

Referring to step 1850 and FIGS. 5A-5E, at least one semiconductor die 700 may be attached to the on-interposer bonding pads 488.

Referring to step 1860 and FIGS. 6-17, a backside portion of the dielectric substrate 410 may be thinned such that bottom end surfaces of the through-dielectric via structures 420 are exposed upon thinning of the backside portion of the dielectric substrate 410.

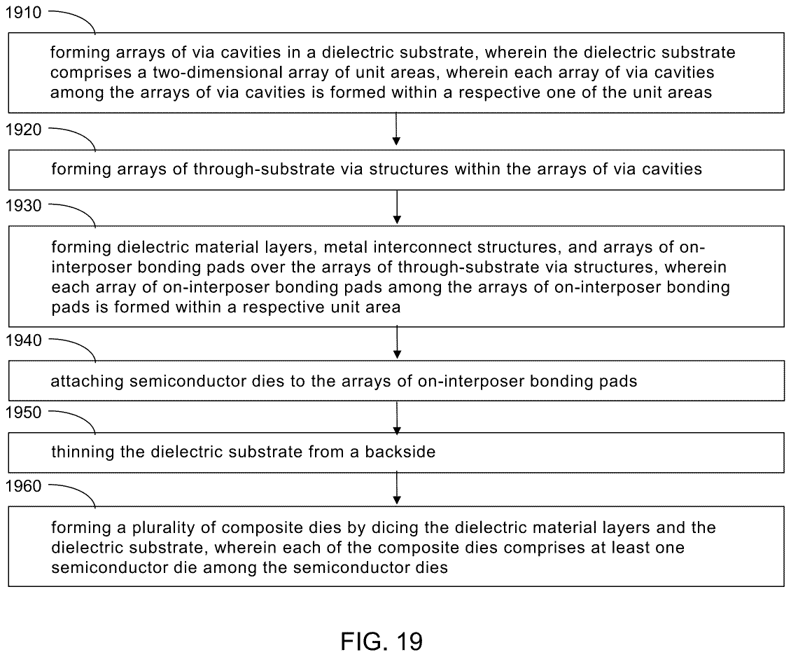

FIG. 19 is a second flowchart illustrating steps for forming a device structure according to an embodiment of the present disclosure.

Referring to step 1910 and FIGS. 1A-2E, arrays of via cavities 419 may be formed in a dielectric substrate 410. The dielectric substrate 410 comprises a two-dimensional array of unit areas UA. Each array of via cavities 419 is formed within a respective one of the unit areas UA.

Referring to step 1920 and FIGS. 3A-3E, arrays of through-substrate via structures 420 may be formed within the arrays of via cavities 419.

Referring to step 1930 and FIGS. 4A-4E, dielectric material layers 460, interconnect-level metal structures (480, 482), and arrays of on-interposer bonding pads 488 may be formed over the arrays of through-substrate via structures 420. Each array of on-interposer bonding pads 488 selected from the arrays of on-interposer bonding pads 488 is formed within a respective unit area UA.

Referring to step 1940 and FIGS. 5A-5E, semiconductor dies 700 may be attached to the arrays of on-interposer bonding pads 488.

Referring to step 1950 and FIGS. 6-9, the dielectric substrate 410 may be thinned from the backside.

Referring to step 1960 and FIGS. 10-17, a plurality of composite dies 800 may be formed by dicing the dielectric material layers 460 and the dielectric substrate 410. Each of the composite dies 800 comprises at least one semiconductor die.

According to various embodiments of the present disclosure, a dielectric interposer 400 comprises a dielectric substrate 410 having through-dielectric via structures 420 providing vertical electrical connections between the metal interconnect structures 480 formed in the dielectric material layers 460 and electrical signal paths in a packaging substrate 200. The dielectric material layers 460 are configured to provide electrical isolation and support for the metal interconnect structures 480, while the through-dielectric via structures 420 provide vertical electrical connections through the dielectric substrate 410. The dielectric interposer 400 includes substrate metallic edge seal structures 430, which prevent crack initiation and propagation at the periphery of the dielectric substrate 410 during dicing and handling processes. Additionally, interconnect-level metallic edge seal structures 482 and bonding-level metallic edge seal structures 486 may be integrated into the dielectric interposer 400 to terminate propagation of cracks in the outer periphery of diced portions of the dielectric substrate 410 that may arise during dicing or subsequent manufacturing steps. The combined functionality of the substrate metallic edge seal structures 430, interconnect-level metallic edge seal structures 482, and bonding-level metallic edge seal structures 486 enhances manufacturing yield by maintaining structural integrity during fabrication. Furthermore, the dielectric stress relief layer 450, composed of a material with a lower Young's modulus than the dielectric material layers 460, mitigates thermal and mechanical stresses during operation, thereby improving the reliability and performance of a semiconductor device package.

A rectangular-shaped dielectric substrate 410 may be used to form the composite dies 800 of the present disclosure. Use of a rectangular-shaped dielectric substrate 410 reduces wasted area of a substrate that is not incorporated into composite dies 800, and thus, increases the manufacturing efficiency for the dielectric interposer 400. The dielectric interposer 400 may be used to provide robust vertical electrical connections while simultaneously reducing thermal and mechanical stress on the metal interconnect structures 480 and the dielectric material layers 460. The dielectric stress relief layer 450 enhances the durability of the overall structure by accommodating stress-induced deformations, improving thermal management, and maintaining the integrity of electrical connections. The substrate metallic edge seal structures 430 absorb and redistribute stress along the periphery of the dielectric substrate 410, preventing the initiation of cracks. The interconnect-level metallic edge seal structures 482 and bonding-level metallic edge seal structures 486 effectively terminate or redirect crack propagation during dicing and other manufacturing processes, ensuring structural stability. The various features of the dielectric interposers 400 of the present disclosure enhance the mechanical robustness, thermal performance, and manufacturing yield of the dielectric interposers 400.

The foregoing outlines features of several embodiments so that those skilled in the art may better understand the aspects of the present disclosure. Each embodiment described using the term “comprises” also inherently discloses additional embodiments in which the term “comprises” is replaced with “consists essentially of” or with the term “consists of,” unless expressly disclosed otherwise herein. Whenever two or more elements are listed as alternatives in a same paragraph of in different paragraphs, a Markush group including a listing of the two or more elements is also impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming an array of via cavities in an upper portion of a dielectric substrate;
forming an array of through-dielectric via structures within the array of via cavities;
forming dielectric material layers and metal interconnect structures over the dielectric substrate, wherein the metal interconnect structures is electrically connected to the array of through-dielectric via structures;
forming on-interposer bonding pads at a topmost level of the dielectric material layers, wherein the on-interposer bonding pads are electrically connected to a respective one of the metal interconnect structures;
attaching at least one semiconductor die to the on-interposer bonding pads; and
thinning a backside portion of the dielectric substrate such that bottom end surfaces of the through-dielectric via structures are exposed upon thinning of the backside portion of the dielectric substrate.

2. The method of claim 1, wherein:
all surfaces of the arrays of via cavities are dielectric surfaces; and
the array of through-dielectric via structures is formed directly on the dielectric surfaces.

3. The method of claim 1, wherein the on-interposer bonding pads are formed by:
patterning pad cavities in the topmost level of the dielectric material layers;
depositing a metallic fill material in the pad cavities and over the topmost level of the dielectric material layers; and
performing a planarization process that removes portions of the metallic fill material from above a horizontal plane including a topmost surface of the dielectric material layers, wherein remaining portions of the metallic fill material in the pad cavities comprise the on-interposer bonding pads.

4. The method of claim 1, wherein:
each of the at least one semiconductor die comprises on-die bonding pads; and
each of the at least one semiconductor die is attached to the on-interposer bonding pads by inducing metal-to-metal bonding between mating pairs of the on-die bonding pads and the on-interposer bonding pads.

5. The method of claim 4, wherein:
a topmost dielectric material layer selected from the dielectric material layers comprises a first silicon oxide layer, wherein the on-interposer bonding pads are laterally surrounded by the first silicon oxide layer; and
each of the at least one semiconductor die comprises a respective second silicon oxide layer that laterally surrounds a respective subset of the on-die bonding pads, and is bonded to a respective surface segment of the first silicon oxide layer via oxide-to-oxide bonding.

6. The method of claim 1, further comprising forming a dielectric die frame around the at least one semiconductor die after attaching the at least one semiconductor die to the on-interposer bonding pads, wherein the dielectric die frame comprises a material selected from a molding compound material and an inorganic dielectric material.

7. The method of claim 1, further comprising:
forming a composite die comprising a portion of the dielectric substrate, the array of through-dielectric via structures, a portion of the dielectric material layers, the metal interconnect structures, and the at least one semiconductor die; and
attaching the composite die to a packaging substrate using an array of solder material portions that is disposed between the through-dielectric via structures and to bonding structures on the packaging substrate.

8. The method of claim 1, further comprising depositing a dielectric stress relief layer comprising a dielectric material having a lower Young's modulus than any material in the dielectric material layers on a top surface of the dielectric substrate, wherein a subset of the metal interconnect structures is formed through the dielectric stress relief layer.

9. The method of claim 1, further comprising:
forming at least one moat trench laterally surrounding the array of via cavities in the dielectric substrate;
forming at least one substrate metallic edge seal structure in the at least one moat trench; and
forming at least one interconnect-level metallic edge seal structure through the dielectric material layers directly on a respective one of the at least one substrate metallic edge seal structure.

10. The method of claim 9, wherein:
the at least one substrate metallic edge seal structure comprises wall portions and lateral protrusion portions that extend outward from the wall portions; and
the method comprises dicing the dielectric material layers, the dielectric substrate, and lateral protrusion portions.

11. A method of forming a device structure, comprising:
forming arrays of via cavities in a dielectric substrate, wherein the dielectric substrate comprises a two-dimensional array of unit areas, wherein each array of via cavities formed within a respective one of the unit areas;
forming arrays of through-substrate via structures within the arrays of via cavities;
forming dielectric material layers, metal interconnect structures, and arrays of on-interposer bonding pads over the arrays of through-substrate via structures, wherein each array of on-interposer bonding pads selected from the arrays of on-interposer bonding pads is formed within a respective unit area;
attaching semiconductor dies to the arrays of on-interposer bonding pads;
thinning the dielectric substrate from a backside; and
forming a plurality of composite dies by dicing the dielectric material layers and the dielectric substrate, wherein each of the composite dies comprises at least one semiconductor die.

12. The method of claim 11, wherein:
each of the semiconductor dies comprises a respective set of on-die bonding pads; and
the respective set of on-die bonding pads is bonded to a respective array of on-interposer bonding pads within the arrays of on-interposer bonding pads by metal-to-metal bonding.

13. The method of claim 11, wherein:
bottom end surfaces of the through-dielectric via structures are exposed upon thinning of the backside portion of the dielectric substrate; and
the method comprises attaching one of the plurality of composite dies to a packaging substrate using an array of solder material portions that is bonded to backside bonding pads that are formed on bottom end surfaces of the through-substrate via structures within said one of the plurality of composite dies, and is bonded to bonding structures on the packaging substrate.

14. The method of claim 11, further comprising depositing a dielectric stress relief layer comprising a dielectric material having a lower Young's modulus than any material in the dielectric material layers on a top surface of the dielectric substrate, wherein the dielectric material layers are deposited over the dielectric stress relief layer and consist of at least one inorganic dielectric material.

15. The method of claim 11, further comprising:
forming moat trenches in the dielectric substrate, wherein each of the moat trenches laterally surrounds a respective array of via cavities selected from the arrays of via cavities;
forming substrate metallic edge seal structure in the moat trenches; and
forming interconnect-level metallic edge seal structure through the dielectric material layers directly on a respective one of the substrate metallic edge seal structures,
wherein each of the plurality of composite dies comprises at least one of the substrate metallic edge seal structures and at least one of the interconnect-level metallic edge seal structures.

16. A device structure comprising:
an array of through-dielectric via structures vertically-extending through a dielectric substrate, wherein each of the through-dielectric via structures comprises a respective substantially straight sidewall that extends from a front surface of the dielectric substrate to a backside surface of the dielectric substrate;
dielectric material layers and metal interconnect structures located over the dielectric substrate;
on-interposer bonding pads located at a topmost level of the dielectric material layers, wherein the on-interposer bonding pads are electrically connected to the array of through-dielectric via structures through the metal interconnect structures; and
at least one semiconductor die attached to the on-interposer bonding pads.

17. The device structure of claim 16, wherein all sidewalls of the through-dielectric via structures are in direct contact with the dielectric substrate.

18. The device structure of claim 16, wherein each of the at least one semiconductor die comprises on-die bonding pads that are bonded to a respective one of the on-interposer bonding pads via metal-to-metal bonding.

19. The device structure of claim 16, further comprising a dielectric stress relief layer comprising a dielectric material having a lower Young's modulus than any material in the dielectric material layers and disposed between the dielectric substrate and the dielectric material layers, wherein a subset of the metal interconnect structures vertically extends through the dielectric stress relief layer.

20. The device structure of claim 16, further comprising:
at least one substrate metallic edge seal structure vertically extending through the dielectric substrate and laterally surrounding the array of through-dielectric via structures; and
at least one interconnect-level metallic edge seal structure vertically extending through the dielectric material layers, located on a respective one of the at least one substrate metallic edge seal structure, and laterally surrounding the metal interconnect structures.
